(19) United States
(12) Patent Application Publication
(10) Pub. No.: US 2020/0119189 A1
(43) Pub. Date: Apr. 16, 2020

(54) HIGH VOLTAGE DEVICE AND MANUFACTURING METHOD THEREOF

(71) Applicant: RICHTEK TECHNOLOGY CORPORATION, Zhubei City (TW)

(72) Inventor: Tsung-Yi Huang, Hsinchu (TW)

(21) Appl. No.: 16/596,835

(22) Filed: Oct. 9, 2019

(30) Foreign Application Priority Data
Oct. 16, 2018 (TW) 107136418

(51) Int. Cl. H01L 29/78; H01L 29/772; H01L 29/808; H01L 29/06; H01L 29/10; H01L 29/423; H01L 29/08

(52) U.S. Cl. CPC H01L 29/7825; H01L 29/7722; H01L 29/8083; H01L 29/0692; H01L 29/0878; H01L 29/4238; H01L 29/42368; H01L 29/0611; H01L 29/1095

(57) ABSTRACT

A high voltage device includes: a semiconductor layer, a well, a body region, a gate, a source, a drain, a drift oxide region, and a top region. The well is formed in the semicoducotor layer. The body region is formed in the well. The gate is formed on the well. The source and the drain are located below, outside, and at different sides of the gate, in the body region and the well respectively. The drift oxide region is formed on a drift region, wherein a bottom surface of the drift oxide region is higher than a first trench bottom surface of the first trench. The top region is formed in the well right below the drift oxide region, and is in contact with the drift oxide region.

### CROSS REFERENCES

The present invention claims priority to TW 107136418 filed on Oct. 16, 2018.

### BACKGROUND OF THE INVENTION

### Field Invention

The present invention relates to a high voltage device and a manufacturing method thereof; particularly, it relates to such high voltage device which has an increased breakdown voltage and a reduced conductive resistance, and a manufacturing method thereof.

### Description of Related Art

FIGS. 1A and 1B show schematic diagrams of a top-view and a cross-section view of a prior art high voltage device 100, respectively. In the context of the present invention, a “high voltage” device refers a device which needs to withstand a voltage over 5V on a drain thereof in normal operation. Typically, the high voltage device 100 has a drift region 12a (as indicated by the dashed frame shown in FIG. 1B) as adrift current channel in an ON operation of the high voltage device 100, wherein the drift region 12a separates a drain 19 and a body region 16 of the high voltage device 100, wherein a lateral length of the drift region 12a is determined according to the threshold voltage that the high voltage device 100 is designed to operate by.

As shown in FIGS. 1A and 1B, the high voltage device 100 includes: a well 12, an isolation region 13, a drift oxide region 14, the body region 16, a body contact 16′, a gate 17, a source 18, and the drain 19. The well 12 has a conductivity type of N-type, and is formed on a substrate 11. The isolation region 13 is a local oxidation of silicon (LOCOS) structure, for defining a device region 13a which is an active area for an operation of the high voltage device 100. The device region 13a has a range which is indicated by the bold dashed frame in FIG. 1A. The gate 17 overlays a part of the drift oxidation region 14. The body region 16 and the body contact 16′ have a conductivity type of P-type. The source 18 and the drain 19 have a conductivity type of N-type.

When the high voltage device 100 operates in the ON operation, electrons flow from the source 18 to the drain 19 through the well 12 as indicated by a folded bold arrow shown in FIG. 1B. In the well 12, N-type impurity concentration decreases downward from top to bottom, wherein a high concentration region 12′ near the top of the well 12 has a highest N-type impurity concentration in the well 12. The folded bold arrow shown in FIG. 1B indicates that the electrons flow through the high concentration region 12′ with a relatively higher N-type impurity concentration and another part of the well 12 with a relatively lower N-type impurity concentration in the drift region 12a. The conductive resistance is relatively lower as the electrons flow through the high concentration region 12′ due to the relatively higher N-type impurity concentration, while the conductive resistance is relatively higher as the electrons flow through another part of the well 12 in the drift region 12a (right below the drift oxide region 14) due to the relatively lower N-type impurity concentration. Therefore, if it is intended to sustain high operation voltage by the high voltage device 100 and the current path is as shown by the folded bold arrow, the series resistance is high. As such, the performance of the high voltage device is not satisfactory.

In view of the above, the present invention provides a high voltage device and a manufacturing method thereof, wherein the high voltage device is not only capable of reducing conductive resistance, but also capable of withstanding a relatively higher operation voltage, to improve the performance of the high voltage device.

### SUMMARY OF THE INVENTION

From one perspective, the present invention provides a high voltage device comprising: a semiconductor layer formed on a substrate, wherein the semiconductor layer has a first trench; a well having a first conductivity type, wherein the well is formed in the semiconductor layer; a body region having a second conductivity type, wherein the body region is formed in the well; a gate formed on the well and in contact with the well; a source and a drain having the first conductivity type, wherein the source and the drain are located at different sides out of the gate respectively, wherein the source is located in the body region, and the drain is located in the well, wherein part of the well between the body region and the drain is a drift region, which serves as a drift current channel in an ON operation of the high voltage device; a drift oxide region formed right above the drift region, wherein the drift oxide region has a bottom surface higher than a first trench bottom of the first trench; and a top region having the second conductivity type, wherein the top region is formed in the well, right below and in contact with the drift oxide region; wherein part of the body region between the source and the well is an inversion region, which serves as an inversion current channel in the ON operation of the high voltage device, wherein the inversion region is located right below the first trench.

From another perspective, the present invention provides a manufacturing method of a high voltage device, comprising: forming a semiconductor layer on a substrate; forming a well having a first conductivity type, wherein the well is formed in the semiconductor layer; forming a top region having the second conductivity type in the well; forming a first trench by etching the semiconductor layer; forming a drift oxide region on the well; forming a body region having a second conductivity type, wherein the body region is formed in the well; forming a gate on the well and in contact with the well; and forming a source and a drain having the first conductivity type, wherein the source and the drain are located at different sides out of the gate respectively, wherein the source is located in the body region, and the drain is located in the well, wherein part of the well between the body region and the drain is a drift region, which serves as a drift current channel in an ON operation of the high voltage device; wherein the drift oxide region is formed right above the drift region, wherein the drift oxide region has a bottom surface higher than a first trench bottom of the first trench; wherein part of the body region between the source and the well is an inversion region, which serves as an inversion current channel in the ON operation of the high voltage device, wherein the inversion region is located right below the first trench; wherein the top region is located right below and in contact with the drift oxide region.

In one preferable embodiment, the drift oxide region includes a local oxidation of silicon (LOCOS) structure, a shallow trench isolation (STI) structure or a chemical vapor deposition (CVD) oxide structure.

In one preferable embodiment, the gate includes: a dielectric layer, which is formed on the body region and the well, and is in contact with the body region and the well; a conductive layer, which is an electrical contact of the gate, and is formed on the dielectric layer and in contact with the dielectric layer; and a spacer layer, which is formed at two sides of the conductive layer, as an electrical insulating layer of the gate.

In one preferable embodiment, the dielectric layer includes a first part and a second part, wherein the first part has a first thickness, and is located right above the inversion region and in contact with the inversion region, and wherein the second part has a second thickness, and is located right above the drift region and in contact with the drift region, wherein the first thickness is smaller than the second thickness.

In one preferable embodiment, the semiconductor layer further includes a second trench, and the drift oxide region is located between the first trench and the second trench, wherein the drain is located right below the second trench in the well, and the bottom of the drift oxide region is higher than a second trench bottom of the second trench.

In one preferable embodiment, the well includes a high concentration region in contact with the body region, wherein an impurity concentration of the high concentration region is higher than an impurity concentration of any other region of the well.

In one preferable embodiment, the first trench has a depth smaller than one micrometer.

In one preferable embodiment, the top region is electrically floating or electrically connected to the source.

From another perspective, the present invention provides a high voltage device comprising: a semiconductor layer formed on a substrate, wherein the semiconductor layer has a first trench; a drift well having a first conductivity type, wherein the drift well is formed in the semiconductor layer; a channel well having a second conductivity type, wherein the channel well is formed in the drift well, and is in contact with the drift well in a channel direction; a buried layer having the first conductivity type, wherein the buried layer is formed below the channel well and in contact with the channel well; a gate formed on part of the channel well and part of the drift well, wherein the gate is in contact with the channel well and the drift well; a source and a drain having the first conductivity type, wherein the source and the drain are located at different sides out of the gate respectively, wherein the source is located in the channel well, and the drain is located in the drift well, wherein part of the drift well between the drain and the channel well is a drift region, which serves as a drift current channel in an ON operation of the high voltage device;

a drift oxide region formed right above the drift region, wherein the drift oxide region has a bottom surface higher than a first trench bottom of the first trench; and a top region having the second conductivity type, wherein the top region is formed in the well, right below and in contact with the drift oxide region; wherein part of the channel well between the source and the drift well in the channel direction is an inversion region, which serves as an inversion current channel in the ON operation of the high voltage device, wherein the inversion region is located right below the first trench.

From another perspective, the present invention provides a manufacturing method of a high voltage device, comprising: forming a buried layer having a first conductivity type in a substrate; forming a semiconductor layer on the substrate; forming a drift well having a first conductivity, wherein the drift well is formed in the semiconductor layer; forming a channel well having a second conductivity type, wherein the channel well is in contact with the drift well in a channel direction, and contacts the buried layer in a vertical direction; forming a top region having the second conductivity type in the well; forming a first trench by etching the semiconductor layer; forming a drift oxide region on the drift well; forming a gate on part of the channel well and part of the drift well, wherein the gate is in contact with the channel well and the drift well; and forming a source and a drain having the first conductivity type, wherein the source and the drain are located at different sides out of the gate respectively, wherein the source is located in the channel well, and the drain is located in the drift well, wherein part of the drift well between the drain and the channel well is a drift region, which serves as a drift current channel in an ON operation of the high voltage device; wherein the drift oxide region has a bottom surface higher than a first trench bottom of the first trench; wherein part of the channel well between the source and the drift well in the channel direction is an inversion region, which serves as an inversion current channel in the ON operation of the high voltage device, wherein the inversion region is located right below the first trench; wherein the buried layer is formed below the channel well and in contact with the channel well; wherein the top region is located right below and in contact with the drift oxide region.

In one preferable embodiment, the drift oxide region includes a local oxidation of silicon (LOCOS) structure, a shallow trench isolation (STI) structure or a chemical vapor deposition (CVD) oxide structure.

In one preferable embodiment, the gate includes: a dielectric layer, which is formed on the channel well and the drift well, and is in contact with the channel well and the drift well; a conductive layer, which is an electrical contact of the gate, and is formed on the dielectric layer and in contact with the dielectric layer; and a spacer layer, which is formed at two sides of the conductive layer, as an electrical insulating layer of the gate.

In one preferable embodiment, the dielectric layer includes a first part and a second part, wherein the first part has a first thickness, and is located right above the inversion region and in contact with the inversion region, and wherein the second part has a second thickness, and is located right above the drift region and in contact with the drift region, wherein the first thickness is smaller than the second thickness.

In one preferable embodiment, the manufacturing method forms a second trench, wherein the drift oxide region is located between the first trench and the second trench; wherein the drain is located right below the second trench in the drift well, and the bottom of the drift oxide region is higher than a second trench bottom of the second trench.

In one preferable embodiment, the drift well includes a high concentration region in contact with the channel well, wherein an impurity concentration of the high concentration region is higher than an impurity concentration of any other region of the drift well.

In one preferable embodiment, the top region is electrically floating or electrically connected to the source.

The objectives, technical details, features, and effects of the present invention will be better understood with regard to the detailed description of the embodiments below.

### BRIEF DESCRIPTION OF THE DRAWINGS

FIGS. 1A and 1B show a top view and a cross-section view of a conventional high voltage device 100, respectively.

FIGS. 2A and 2B show a first embodiment of the present invention.

FIG. 3 shows a second embodiment of the present invention.

FIG. 4 shows a third embodiment of the present invention.

FIG. 5 shows a fourth embodiment of the present invention.

FIG. 6 shows a fifth embodiment of the present invention.

FIG. 7 shows a sixth embodiment of the present invention.

FIG. 8 shows a seventh embodiment of the present invention.

FIG. 9 shows an eighth embodiment of the present invention.

FIG. 10 shows a ninth embodiment of the present invention.

FIG. 11 shows a tenth embodiment of the present invention.

FIGS. 12A-12H shows an eleventh embodiment of the present invention.

FIGS. 13A-13F shows a twelfth embodiment of the present invention.

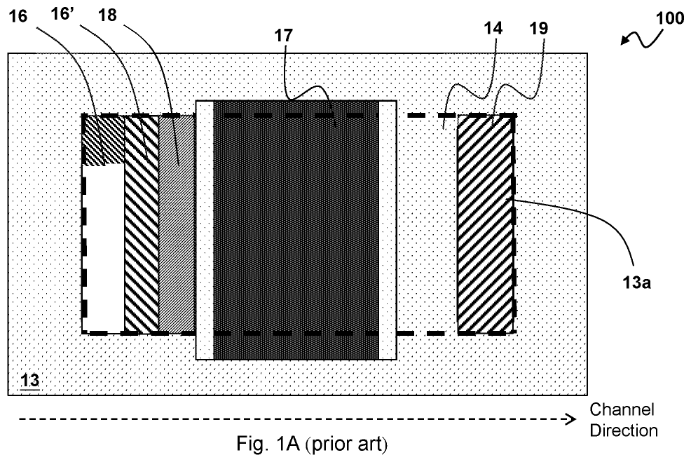

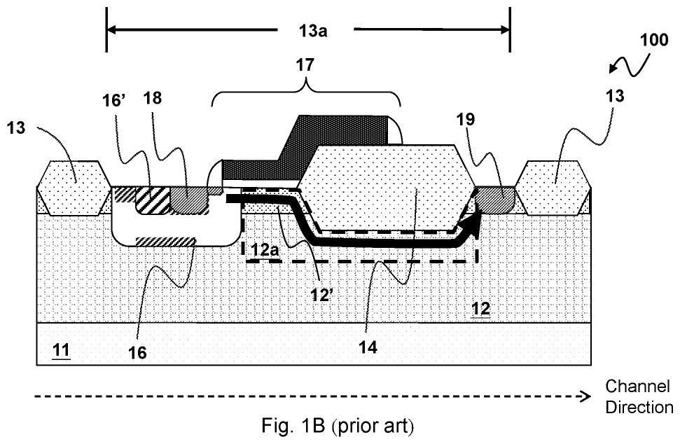

### DESCRIPTION OF THE PREFERABLE EMBODIMENTS

The drawings as referred to throughout the description of the present invention are for illustration only, to show the interrelations among the process steps and the layers, but the shapes, thicknesses, and widths are not drawn in actual scale.

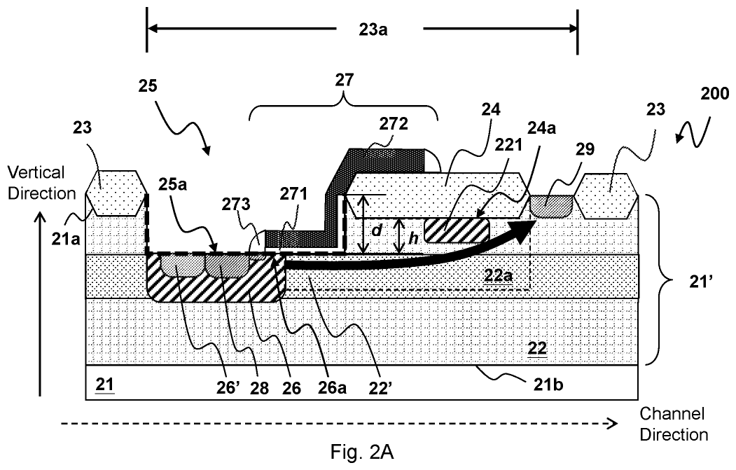

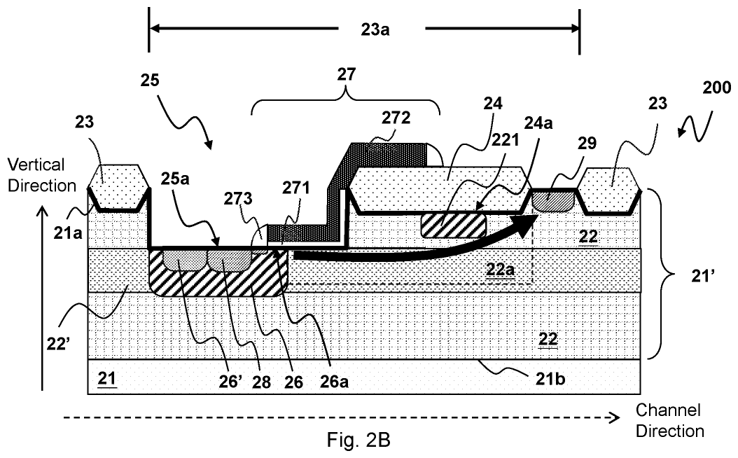

Please refer to FIGS. 2A and 2B, which show a first embodiment of the present invention. FIG. 2A shows a cross-section view of a high voltage device 200. As show in FIGS. 2A and 2B, the high voltage device 200 includes a semiconductor layer 21′, a well 22, an isolation region 23, a drift oxide region 24, a body region 26, a body contact 26′, a gate 27, a source 28, a drain 29, and a top region 221. In the high voltage device 200, the semiconductor layer 21′, the well 22, the drift oxide region 24, the body region 26, the gate 27, the source 28, the drain 29, and the top region 221 are basic features according to the present invention, while the isolation region 23 and the body contact 26′ are additional features. The semiconductor layer 21′ is formed on the substrate 21, wherein the semiconductor layer 21′ has a top surface 21a and a bottom surface 21b opposite to the top surface 21a in a vertical direction (as indicated by the direction of the solid arrow in FIGS. 2A and 2B). The substrate 21 is, for example but not limited to, a P-type or N-type silicon substrate. The semiconductor layer 21′, for example, is formed on the substrate 21 by an epitaxial growth process step, or is a part of the substrate 21. The semiconductor layer 21′ can be formed by various methods known to a person having ordinary skill in the art, so the details thereof are not redundantly explained here.

Still referring to FIGS. 2A and 2B, the isolation region 23 is formed on and in contact with the top surface 21a for defining an operation region 23a. The isolation region 23 is not limited to a local oxidation of silicon (LOCOS) structure as shown in the figures, and may be a shallow trench isolation (STI) structure or a chemical vapor deposition (CVD) oxide structure. The drift oxide region 24 is formed on and in contact with the top surface 21a and is located on and in contact with part of a drift region 22a (as indicated by the dashed line frames shown in FIGS. 2A and 2B) in the operation region 23a. The drift oxide region 24 can be formed, for example, by the same process steps which form the isolation region 23, so that the drift oxide region 24 and the isolation region 23 are formed at the same time.

The semiconductor layer 21′ has a first trench 25 as indicated by a dashed bold folded line shown in FIG. 2A. In one prefereable embodiment, after the well 22 is formed, the first trench 25 is formed by a lithography process step and an etch process step. Thus, the bottom surface 24a of the drift oxide region 24 is higher than the first trench bottom 25a of the first trench 25 in the vertical direction. In one preferable embodiment, a high concentration region 22′ is arranged to be located beneath and in contact with the first trench bottom 25a. As shown in FIG. 2A, the first trench 25 has a depth d, and the bottom surface 24a of the drift oxide region 24 is higher than the first trench bottom 25a by a height h. As thus, when the high voltage device 200 operates in an ON operation, carriers with a first conductivity type flow mostly through the high concentration region 22′ in the drift region 22a, which has a relatively lower conductive resistance compared to the prior art high voltage device 100. In one preferable embodiment, the depth d of the first trench 25 is smaller than one micrometer.

The well 22 has the first conductivity type, and is formed in the operation region 23a of the semiconductor layer 21′. The well 22 is located beneath the top surface 21a and is in contact with the top surface 21a in the vertical direction. In one preferable embodiment, the well 22 includes the high concentration region 22′. The impurity concentration of the first conductivity type impurities of the high concentration region 22′ is higher than an impurity concentration of any other region of the well 22. The well is formed by for example but not limited to plural ion implantation process steps, wherein at least one of the ion implantation process steps forms the high concentration region 22′. In one preferable embodiment, the high concentration region 22′ is in contact with the body region 26, and serves as a major channel for the first conductivity type carriers to flow through, whereby the first conductivity type carriers flow mostly through the drift region 22a. Therefore, the high voltage device 200 according to the present invention has a relatively lower conductive resistance as compared to the prior art.

The body region 26 has a second conductivity type, and is formed in the well 22 in the operation region 23a. The body region 26 is located beneath and in contact with the top surface 21a in the vertical direction. The body region 26 contacts the high concentration region 22′ of the well 22 in the channel direction (as indicated by the dashed arrow in the figure). The body contact 26′ has the second conductivity type, and is an electrical contact of the body region 26. The body contact 26′ is formed in the body region 26, beneath the top surface 21a and in contact with the top surface 21a in the vertical direction. The gate 27 is formed on the top surface 21a of the semiconductor layer 21′ in the operation region 23a. Part of the body region 26 near the top surface 21a, under the gate 27 in the vertical direction and between the source 28 and the well 22 in the channel direction, is an inversion region 26a, which serves as an inversion current channel in the ON operation of the high voltage device 200, wherein the inversion region 26a is located right below the gate 27 and in contact with the gate 27, and the inversion region 26a is located right below the first trench 25.

Still referring to FIGS. 2A and 2B, the source 28 and the drain 29 have the first conductivity type. The source 28 and the drain 29 are formed in the operation region 23a, beneath the top surface 21a and in contact with the top surface 21a in the vertical direction. The source 28 and the drain 29 are located at two different sides out of the gate 27 respectively, wherein the source 28 is located in the body region 26, at one side of the gate 27, and the drain 29 is located in the well 22 at the other side of the gate 27 which is away from the body region 26. Part of the well 22 which is near the top surface 21a, and between the body region 26 and the drain 29 in the channel direction, is the drift region 22a. The drift region 22a serves as a drift current channel in an ON operation of the high voltage device 200.

Still referring to FIGS. 2A and 2B, the top region 221 has the second conductivity type, and is formed in the well 22, right below and in contact with the drift oxide region 24. The top region 221 increases the breakdown voltage of the high voltage device 200. In one preferable embodiment, the top region 221 is electrically floating or electrically connected to the source 28. When the top region 221 is electrically floating, the conductive resistance of the high voltage device 200 is decreased, and the breakdown voltage of the high voltage device 200 is increased. When the top region 221 is electrically connected to the source 28, a super junction is formed between the top region 221 and part of the well 22 around the top region 221, whereby the conductive resistance of the high voltage device 200 is decreased and the breakdown voltage of the high voltage device 200 is increased as well.

Note that the term “inversion current channel” means thus. Taking this embodiment as an example, when the high voltage device 200 operates in the ON operation due to the voltage applied to the gate 27, an inversion layer is formed beneath the gate 27, between the source 28 and the drift region 22a, so that a conduction current flows through the region of the inversion layer, which is the inversion current channel known to a person having ordinary skill in the art.

Note that the first conductivity type may be P-type or N-type; when the first conductivity type is P-type, the second conductivity type is N-type, and when the first conductivity type is N-type, the second conductivity type is P-type.

Note that the term “drift current channel” means thus. Taking this embodiment as an example, the drift region refers to a region where the conduction current passes through in a drifting manner when the high-voltage device 200 operates in ON operation, which is known to a person having ordinary skill in the art.

Note that the top surface 21a as referred to does not mean a completely flat plane but refers to the surface of the semiconductor layer 21′, as indicated by a thick line in FIG. 2B. In the present embodiment, for example, a part of the top surface 21a where the drift oxide region 24 is in contact with has a recessed portion.

Note that the gate 27 as defined in the context of this invention includes a dielectric layer 271 in contact with the top surface 21a, a conductive layer 272 which is conductive, and a spacer layer 273 which is electrically insulative. The dielectric layer 271 is formed on the body region 26 and the well 22, and is in contact with the body region 26 and the well 22. The conductive layer 272 is an electrical contact of the gate 27, and is formed on the dielectric layer 271 and in contact with the dielectric layer 271. The spacer layer 273 is formed out of two sides of the conductive layer 272, as an electrical isolation layer of the gate 27.

In addition, the term “high voltage” device means that, when the device operates in normal operation, the voltage applied to the drain is higher than a specific voltage, such as 5V; for devices of different high voltages, a lateral distance (distance of the drift region 22a) between the body region 26 and the drain 29 can be determined according to the operation voltage that the device is designed to withstand during normal operation, which is known to a person having ordinary skill in the art.

Note that, by stating that “the bottom surface 24a of the drift oxide region 24 is higher than the first trench bottom 25a of the first trench 25 in the vertical direction”, it means that the distance from the bottom surface 24a of the drift oxide region 24 to the bottom surface 21b of the semiconductor layer 21′ is farther than the distance from the first trench bottom 25a of the first trench 25 to the bottom surface 21b of the semiconductor layer 21′ in the vertical direction.

The present invention is superior to the prior art in that: taking the embodiment shown in FIGS. 2A and 2B as an example, according to the present invention, when the high voltage device 200 operates in the ON operation, the first conductivity type carriers flow mostly through the high concentration region 22′ of the drift region 22a, to reduce the conductive resistance. Besides, when the high voltage device 200 operates in the ON operation, a region in the drift region 22a above the high concentration region 22′ is also part of the drift current channel, and thus, the drift current channel of the present invention is relatively wider as compared to the prior art, whereby the conductive resistance is further reduced. Therefore, the performance of the high voltage device according to the present invention is improved.

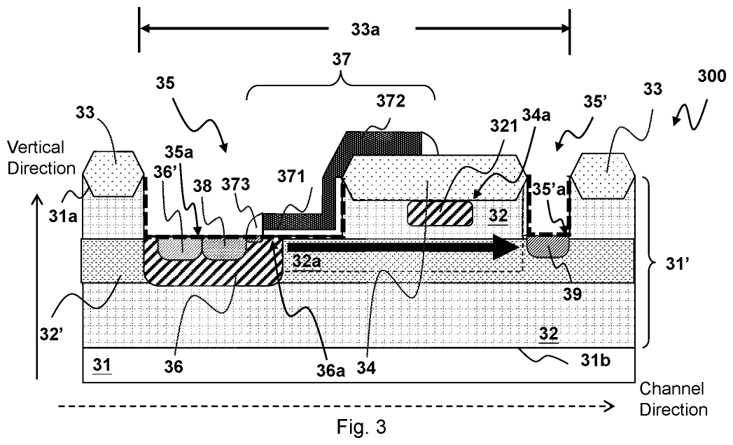

Please refer to FIG. 3, which shows a second embodiment of the present invention. FIG. 3 shows a cross-section view of a high voltage device 300. As show in FIG. 3, the high voltage device 300 includes a semiconductor layer 31′, a well 32, an isolation region 33, a drift oxide region 34, a body region 36, a body contact 36′, a gate 37, a source 38, and a drain 39. The semiconductor layer 31′ is formed on the substrate 31, and has a top surface 31a and a bottom surface 31b opposite to the top surface 31a in the vertical direction (as indicated by the direction of a solid arrow shown in FIG. 3). The substrate 31 is, for example but not limited to, a P-type or N-type silicon substrate. The semiconductor layer 31′, for example, is formed on the substrate 31 by an epitaxial process step, or is a part of the substrate 31. The semiconductor layer 31′ can be formed by various methods as known to a person having ordinary skill in the art, so the details thereof are not redundantly explained here.

Still referring to FIG. 3, the isolation region 33 is formed on and in contact with the top surface 31a, for defining an operation region 33a. The isolation region 33 is not limited to a local oxidation of silicon (LOCOS) structure as shown in FIG. 3, and may instead be a shallow trench isolation (STI) structure or a chemical vapor deposition (CVD) oxide structure. The drift oxide region 34 is formed on and in contact with the top surface 31a, and is located on and in contact with part of the drift region 32a (as indicated by the dashed line frame in FIG. 3) in the operation region 33a. In this embodiment, the drift oxide region 34 can be formed, for example, by the same process steps which form the isolation region 23, so that the drift oxide region 24 and the isolation region 23 are formed at the same time.

As indicated by a bold dashed folded line shown in FIG. 3, the semiconductor layer 31′ includes a first trench 35 and a second trench 35′. In a preferable embodiment, after the well 32 is formed, the first trench 35 and the second trench 35′ are formed by a lithography process step and an etch process step. Thus, the bottom surface 34a of the drift oxide region 34 is higher than the first trench bottom 35a of the first trench 35 and the second trench bottom 35′a of the second trench 35′. In one preferable embodiment, a high concentration region 32′ is arranged to be located beneath and in contact with the first trench bottom 35 and the second trench 35′. This embodiment is different from the first embodiment in that, in this embodiment, the semiconductor layer 31′ further includes the second trench 35′. As thus, when the high voltage device 300 operates in the ON operation, the first conductivity type carriers flow even more through the high concentration region 32′ as compared to the first embodiment, to further reduce the conductive resistance. In a preferable embodiment, both the depths of the first trench 35 and the second trench 35′ are smaller than one micrometer.

The well 32 has the first conductivity type, and is formed in the operation region 33a of the semiconductor layer 31′, and the well 32 is located beneath the top surface 31a and in contact with the top surface 31a in the vertical direction. In one preferable embodiment, the well 32 includes the high concentration region 32′. The impurity concentration of the first conductivity type impurities of the high concentration region 32′ is higher than the impurity concentration of any other region of the well 32. The well is formed by for example but not limited to plural ion implantation process steps, wherein at least one of the ion implantation process steps forms the high concentration region 32′. In one preferable embodiment, the high concentration region 32′ is in contact with the body region 36, and serves as a major channel for the first conductivity type carriers to flow through, whereby the first conductivity type carriers flow mostly through the drift region 32a. Therefore, the high voltage device 300 according to the present invention has a relatively lower conductive resistance as compared to the prior art.

The body region 36 has a second conductivity type, and is formed in the well 32 in the operation region 33a. The body region 36 is located beneath and in contact with the top surface 31a in the vertical direction. The body region 36 contacts the high concentration region 32′ of the well 32 in the channel direction (as indicated by the dashed arrow in the figure). The body contact 36′ has the second conductivity type, and is an electrical contact of the body region 36. The body contact 36′ is formed in the body region 36, beneath the top surface 31a and in contact with the top surface 31a in the vertical direction. The gate 37 is formed on the top surface 31a of the semiconductor layer 31′ in the operation region 33a. Part of the body region 36 near the top surface 31a, under the gate 37 in the vertical direction and between the source 38 and the well 32 in the channel direction, is an inversion region 36a, which serves as an inversion current channel in the ON operation of the high voltage device 300, wherein the inversion region 36a is located right below the gate 37 and in contact with the gate 37, and the inversion region 36a is located right below the first trench 35.

Still referring to FIG. 3, the source 38 and the drain 39 have the first conductivity type. The source 38 and the drain 39 are formed in the operation region 33a, beneath the top surface 31a and in contact with the top surface 31a in the vertical direction. The source 38 and the drain 39 are located at two different sides out of the gate 37 respectively, wherein the source 38 is located in the body region 36, at one side of the gate 37, and the drain 39 is located in the well 32 at the other side of the gate 37 which is away from the body region 36. Part of the well 32 which is near the top surface 31a, and between the body region 36 and the drain 39 in the channel direction, is the drift region 32a. The drift region 32a serves as a drift current channel in an ON operation of the high voltage device 300.

Still referring to FIG. 3, the top region 321 has the second conductivity type, and is formed in the well 32, right below and in contact with the drift oxide region 34. The top region 321 increases the breakdown voltage of the high voltage device 300. In one preferable embodiment, the top region 321 is electrically floating or electrically connected to the source 38. When the top region 321 is electrically floating, the conductive resistance of the high voltage device 300 is decreased, and the breakdown voltage of the high voltage device 300 is increased. When the top region 321 is electrically connected to the source 38, a super junction is formed between the top region 321 and part of the well 32 around the top region 321, whereby the conductive resistance of the high voltage device 300 is decreased and the breakdown voltage of the high voltage device 300 is increased as well.

Note that the gate 37 as defined in the context of this invention includes a dielectric layer 371 in contact with the top surface 31a, a conductive layer 372 which is conductive, and a spacer layer 373 which is electrically insulative. The dielectric layer 371 is formed on the body region 36 and the well 32, and is in contact with the body region 36 and the well 32. The conductive layer 372 is an electrical contact of the gate 37, and is formed on the dielectric layer 371 and in contact with the dielectric layer 371. The spacer layer 373 is formed at two sides of the conductive layer 372, as an electrical insulating layer of the gate 37.

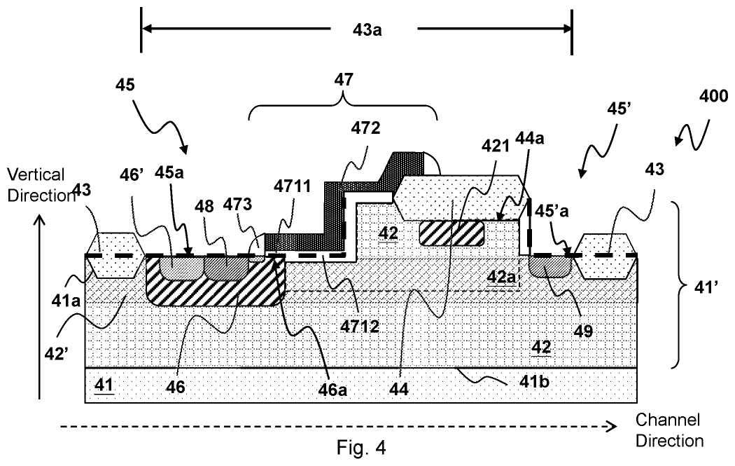

Please refer to FIG. 4, which shows a third embodiment of the present invention. FIG. 4 shows a cross-section view of a high voltage device 400. As show in FIG. 4, the high voltage device 400 includes a semiconductor layer 41′, a well 42, an isolation region 43, a drift oxide region 44, a body region 46, a body contact 46′, a gate 47, a source 48, a drain 49, and a top region 421. The semiconductor layer 41′ which is formed on the substrate 41 has a top surface 41a and a bottom surface 41b opposite to the top surface 41a in the vertical direction (as indicated by the direction of the solid arrow in FIG. 4). The substrate 41 is, for example but not limited to, a P-type or N-type silicon substrate. The semiconductor layer 41′, for example, is formed on the substrate 41 by an epitaxial growth process step, or is a part of the substrate 41. The semiconductor layer 41′ can be formed by various methods known to a person having ordinary skill in the art, so the details thereof are not redundantly explained here.

Still referring to FIG. 4, the isolation region 43 is formed on and in contact with the top surface 41a, for defining an operation region 43a. The isolation region 43 is not limited to a local oxidation of silicon (LOCOS) structure as shown in FIG. 4, and may be a shallow trench isolation (STI) structure or a chemical vapor deposition (CVD) oxide structure. The drift oxide region 44 is formed on and in contact with the top surface 41a, and is located on and in contact with part of the drift region 42a (as indicated by the dashed line frame in FIG. 4) in the operation region 43a. In this embodiment, the drift oxide region 44 can be formed, for example, by the same process steps which form the isolation region 43, so that the drift oxide region 44 and the isolation region 43 are formed at the same time.

As indicated by a bold dashed folded line shown in FIG. 4, the semiconductor layer 41′ includes a first trench 45 and a second trench 45′. In a preferable embodiment, after the well 42 is formed, the first trench 45 and the second trench 45′ are formed by a lithography process step and an etch process step. Thus, the bottom surface 44a of the drift oxide region 44 is higher than the first trench bottom 45a of the first trench 45 and is higher than the second trench bottom 45′a of the second trench 45′. In one preferable embodiment, a high concentration region 42′ is arranged to be located beneath and in contact with the first trench bottom 45 and the second trench 45′. As thus, when the high voltage device 400 operates in the ON operation, the first conductivity type carriers flow even more through the high concentration region 42′ as compared to the first embodiment, to further reduce the conductive resistance. In a preferable embodiment, both the depths of the first trench 45 and the second trench 45′ are smaller than one micrometer.

The well 42 has the first conductivity type, and is formed in the operation region 43a of the semiconductor layer 41′, and the well 42 is located beneath the top surface 41a and in contact with the top surface 41a in the vertical direction. In one preferable embodiment, the well 42 includes the high concentration region 42′. The impurity concentration of the first conductivity type impurities of the high concentration region 42′ is higher than the impurity concentration of any other region of the well 42. The well is formed by for example but not limited to plural ion implantation process steps, wherein at least one of the ion implantation process steps forms the high concentration region 42′. In one preferable embodiment, the high concentration region 42′ is in contact with the body region 46, and serves as a major channel for the first conductivity type carriers to flow through, whereby the first conductivity type carriers flow mostly through the drift region 42a. Therefore, the high voltage device 400 according to the present invention has a relatively lower conductive resistance as compared to the prior art.

The body region 46 has a second conductivity type, and is formed in the well 42 in the operation region 43a. The body region 46 is located beneath and in contact with the top surface 41a in the vertical direction. The body region 46 contacts the high concentration region 42′ of the well 42 in the channel direction (as indicated by the dashed arrow in the figure). The body contact 46′ has the second conductivity type, and is an electrical contact of the body region 46. The body contact 46′ is formed in the body region 46, beneath the top surface 41a and in contact with the top surface 41a in the vertical direction. The gate 47 is formed on the top surface 41a of the semiconductor layer 41′ in the operation region 43a. Part of the body region 46 near the top surface 41a, under the gate 47 in the vertical direction and between the source 48 and the well 42 in the channel direction, is an inversion region 46a, which serves as an inversion current channel in the ON operation of the high voltage device 400, wherein the inversion region 46a is located right below the gate 47 and in contact with the gate 47, and the inversion region 46a is located right below the first trench 45.

Still referring to FIG. 4, the source 48 and the drain 49 have the first conductivity type. The source 48 and the drain 49 are formed in the operation region 43a, beneath the top surface 41a and in contact with the top surface 41a in the vertical direction. The source 48 and the drain 49 are located at two different sides out of the gate 47 respectively, wherein the source 48 is located in the body region 46, at one side of the gate 47, and the drain 49 is located in the well 42 at the other side of the gate 47 which is away from the body region 46. Part of the well 42 which is near the top surface 41a, and between the body region 46 and the drain 49 in the channel direction, is the drift region 42a. The drift region 42a serves as a drift current channel in an ON operation of the high voltage device 400.

Still referring to FIG. 4, the top region 421 has the second conductivity type, and is formed in the well 42, right below and in contact with the drift oxide region 44. The top region 421 increases the breakdown voltage of the high voltage device 400. In one preferable embodiment, the top region 421 is electrically floating or electrically connected to the source 48. When the top region 421 is electrically floating, the conductive resistance of the high voltage device 400 is decreased, and the breakdown voltage of the high voltage device 400 is increased. When the top region 421 is electrically connected to the source 48, a super junction is formed between the top region 421 and part of the well 42 around the top region 421, whereby the conductive resistance of the high voltage device 400 is decreased and the breakdown voltage of the high voltage device 400 is increased as well.

Note that the gate 47 includes a dielectric layer 471 (including a first part 4711 and a second part 4712) in contact with the top surface 41a, a conductive layer 472 which is conductive, and a spacer layer 473 which is electrically insulative. The dielectric layer 471 is formed on the body region 46 and the well 42, and is in contact with the body region 46 and the well 42. The conductive layer 472 is an electrical contact of the gate 47, and is formed on the dielectric layer 471 and in contact with the dielectric layer 471. The spacer layer 473 is formed at two sides of the conductive layer 472, as an electrical insulating layer of the gate 47.

This embodiment is different from the second embodiment in that, in this embodiment, the isolation region 43 for example is located right above the first trench 45 and the second trench 45′. Besides, in this embodiment, the dielectric layer includes the first part 4711 and the second part 4712, wherein the first part 4711 has a first thickness, and is located right above the inversion region and in contact with the inversion region 46a, and wherein the second part 4712 has a second thickness, and is located right above the drift region 42a and in contact with the drift region 42a, wherein the first thickness is smaller than the second thickness. Furthermore, in this embodiment, the drift oxide region 44 is not in close neighboring to the first trench 45, i.e., the drift oxide region 44 is located between the first trench 45 and the second trench 45′, but the drift oxide region 44 is not in contact with the first trench 45. (In another embodiment, the drift oxide region 44 is also not in contact with the second trench 45′.) Note that the thickness range of the dielectric layer (including the first part and the second part) is from several to hundreds angstroms, which is different from the thickness range of the LOCOS structure, STI structure, and CVD oxide structure. The thickness range of the LOCOS structure, STI structure, and CVD oxide structure is larger than one thousand angstroms. The function of the dielectric layer of the gate is different from the isolation region and the drift oxide region, as well known to a person having ordinary skill in the art, so the details thereof are not redundantly explained here.

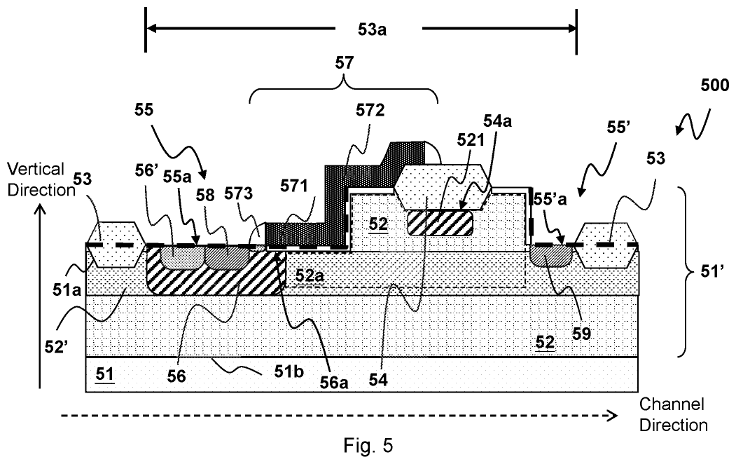

Please refer to FIG. 5, which shows a fourth embodiment of the present invention. FIG. 5 shows a cross-section view of a high voltage device 500. As show in FIG. 5, the high voltage device 500 includes a semiconductor layer 51′, a well 52, an isolation region 53, a drift oxide region 54, a body region 56, a body contact 56′, a gate 57, a source 58, a drain 59, and a top region 521. The semiconductor layer 51′ which is formed on the substrate 51 has a top surface 51a and a bottom surface 51b opposite to the top surface 51a in the vertical direction (as indicated by the direction of the solid arrow in FIG. 5). The substrate 51 is, for example but not limited to, a P-type or N-type silicon substrate. The semiconductor layer 51′, for example, is formed on the substrate 51 by an epitaxial growth process step, or is a part of the substrate 51. The semiconductor layer 51′ can be formed by various methods known to a person having ordinary skill in the art, so the details thereof are not redundantly explained here.

Still referring to FIG. 5, the isolation region 53 is formed on and in contact with the top surface 51a, for defining an operation region 53a. The isolation region 53 is not limited to a local oxidation of silicon (LOCOS) structure as shown in FIG. 5, and may be a shallow trench isolation (STI) structure or a chemical vapor deposition (CVD) oxide structure. The drift oxide region 54 is formed on and in contact with the top surface 51a, and is located on and in contact with part of the drift region 52a (as indicated by the dashed line frame in FIG. 5) in the operation region 53a. In this embodiment, the drift oxide region 54 can be formed, for example, by the same process steps which form the isolation region 53, so that the drift oxide region 54 and the isolation region 53 are formed at the same time.

As indicated by a bold dashed folded line shown in FIG. 5, the semiconductor layer 51′ includes a first trench 55 and a second trench 55′. In a preferable embodiment, after the well 52 is formed, the first trench 55 and the second trench 55′ are formed by a lithography process step and an etch process step. Thus, the bottom surface 54a of the drift oxide region 54 is higher than the first trench bottom 55a of the first trench 55 and is higher than the second trench bottom 55′a of the second trench 55′. In one preferable embodiment, a high concentration region 52′ is arranged to be located beneath and in contact with the first trench bottom 55 and the second trench 55′. As thus, when the high voltage device 500 operates in the ON operation, the first conductivity type carriers flow even more through the high concentration region 52′ as compared to the first embodiment, to further reduce the conductive resistance. In a preferable embodiment, both the depths of the first trench 55 and the second trench 55′ are smaller than one micrometer.

The well 52 has the first conductivity type, and is formed in the operation region 53a of the semiconductor layer 51′, and the well 52 is located beneath the top surface 51a and in contact with the top surface 41a in the vertical direction. In one preferable embodiment, the well 52 includes the high concentration region 52′. The impurity concentration of the first conductivity type impurities of the high concentration region 52′ is higher than the impurity concentration of any other region of the well 52. The well is formed by for example but not limited to plural ion implantation process steps, wherein at least one of the ion implantation process steps forms the high concentration region 52′. In one preferable embodiment, the high concentration region 52′ is in contact with the body region 56, and serves as a major channel for the first conductivity type carriers to flow through, whereby the first conductivity type carriers flow mostly through the drift region 52a. Therefore, the high voltage device 500 according to the present invention has a relatively lower conductive resistance as compared to the prior art.

The body region 56 has a second conductivity type, and is formed in the well 52 in the operation region 53a. The body region 56 is located beneath and in contact with the top surface 51a in the vertical direction. The body region 56 contacts the high concentration region 52′ of the well 52 in the channel direction (as indicated by the dashed arrow in the figure). The body contact 56′ has the second conductivity type, and is an electrical contact of the body region 56. The body contact 56′ is formed in the body region 56, beneath the top surface 51a and in contact with the top surface 51a in the vertical direction. The gate 57 is formed on the top surface 51a of the semiconductor layer 51′ in the operation region 53a. Part of the body region 56 near the top surface 51a, under the gate 57 in the vertical direction and between the source 58 and the well 52 in the channel direction, is an inversion region 56a, which serves as an inversion current channel in the ON operation of the high voltage device 500, wherein the inversion region 56a is located right below the gate 57 and in contact with the gate 57, and the inversion region 56a is located right below the first trench 55.

Still referring to FIG. 5, the source 58 and the drain 59 have the first conductivity type. The source 58 and the drain 59 are formed in the operation region 53a, beneath the top surface 51a and in contact with the top surface 51a in the vertical direction. The source 58 and the drain 59 are located at two different sides out of the gate 57 respectively, wherein the source 58 is located in the body region 56, at one side of the gate 57, and the drain 59 is located in the well 52 at the other side of the gate 57 which is away from the body region 56. Part of the well 52 which is near the top surface 51a, and between the body region 56 and the drain 59 in the channel direction, is the drift region 52a. The drift region 52a serves as a drift current channel in an ON operation of the high voltage device 500.

Still referring to FIG. 5, the top region 521 has the second conductivity type, and is formed in the well 52, right below and in contact with the drift oxide region 54. The top region 521 increases the breakdown voltage of the high voltage device 500. In one preferable embodiment, the top region 521 is electrically floating or electrically connected to the source 58. When the top region 521 is electrically floating, the conductive resistance of the high voltage device 500 is decreased, and the breakdown voltage of the high voltage device 500 is increased. When the top region 521 is electrically connected to the source 58, a super junction is formed between the top region 521 and part of the well 52 around the top region 521, whereby the conductive resistance of the high voltage device 500 is decreased and the breakdown voltage of the high voltage device 500 is increased as well.

Note that the gate 57 includes a dielectric layer 571 in contact with the top surface 51a, a conductive layer 572 which is conductive, and a spacer layer 573 which is electrically insulative. The dielectric layer 571 is formed on the body region 56 and the well 52, and is in contact with the body region 56 and the well 52. The conductive layer 572 is an electrical contact of the gate 57, and is formed on the dielectric layer 571 and in contact with the dielectric layer 571. The spacer layer 573 is formed at two sides of the conductive layer 572, as an electrical insulating layer of the gate 57.

This embodiment is different from the third embodiment in that, in this embodiment, the drift oxide region 54 is not in contact with the second trench 55′.

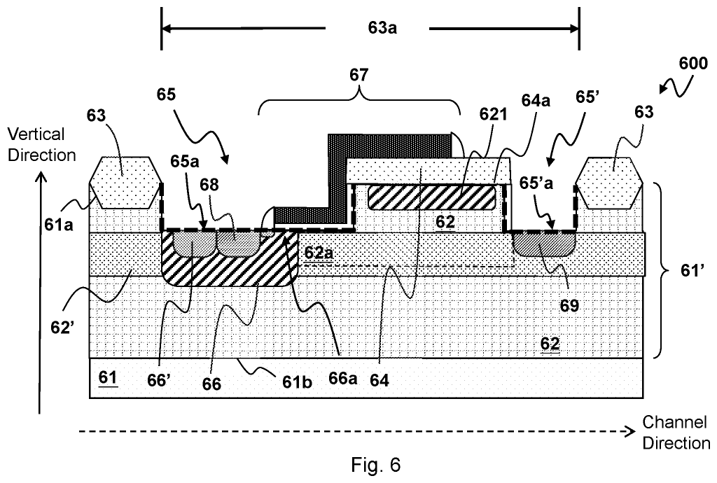

Please refer to FIG. 6, which shows a fifth embodiment of the present invention. FIG. 6 shows a cross-section view of a high voltage device 600. As show in FIG. 6, the high voltage device 600 includes a semiconductor layer 61′, a well 62, an isolation region 63, a drift oxide region 64, a body region 66, a body contact 66′, a gate 67, a source 68, a drain 69, and a top region 621. The semiconductor layer 61′ is formed on the substrate 61, and has a top surface 61a and a bottom surface 61b opposite to the top surface 61a in the vertical direction (as indicated by the direction of a solid arrow shown in FIG. 6, and the same hereinafter). The substrate 61 is, for example but not limited to, a P-type or N-type silicon substrate. The semiconductor layer 61′, for example, is formed on the substrate 61 by an epitaxial growth process step, or is a part of the substrate 61. The semiconductor layer 61′ can be formed by various methods as known to a person having ordinary skill in the art, so the details thereof are not redundantly explained here.

Still referring to FIG. 6, the isolation region 63 is formed on and in contact with the top surface 61a, for defining an operation region 63a. The isolation region 63 is not limited to a local oxidation of silicon (LOCOS) structure as shown in FIG. 6, and may be a shallow trench isolation (STI) structure or a chemical vapor deposition (CVD) oxide structure. The drift oxide region 64 is formed on and in contact with the top surface 61a, and is located on and in contact with part of the drift region 62a (as indicated by the dashed line frame in FIG. 6) in the operation region 63a. In this embodiment, the drift oxide region 64 is for example a chemical vapor deposition (CVD) oxide structure as shown.

As indicated by a bold dashed folded line shown in FIG. 6, the semiconductor layer 61′ includes a first trench 65 and a second trench 65′. In a preferable embodiment, after the well 62 is formed, the first trench 65 and the second trench 65′ are formed by a lithography process step and an etch process step. Thus, the bottom surface 64a of the drift oxide region 64 is higher than the first trench bottom 65a of the first trench 65 and is higher than the second trench bottom 65′a of the second trench 65′. In one preferable embodiment, a high concentration region 62′ is arranged to be located beneath and in contact with the first trench bottom 65 and the second trench 65′. As thus, when the high voltage device 600 operates in the ON operation, the first conductivity type carriers flow even more through the high concentration region 62′ as compared to the first embodiment, to further reduce the conductive resistance. In a preferable embodiment, both the depths of the first trench 65 and the second trench 65′ are smaller than one micrometer.

The well 62 has the first conductivity type, and is formed in the operation region 63a of the semiconductor layer 61′, and the well 62 is located beneath the top surface 31a and in contact with the top surface 61a in the vertical direction. In one preferable embodiment, the well 62 includes the high concentration region 62′. The impurity concentration of the first conductivity type impurities of the high concentration region 62′ is higher than the impurity concentration of any other region of the well 62. The well is formed by for example but not limited to plural ion implantation process steps, wherein at least one of the ion implantation process steps forms the high concentration region 62′. In one preferable embodiment, the high concentration region 62′ is in contact with the body region 66, and serves as a major channel for the first conductivity type carriers to flow through, whereby the first conductivity type carriers flow mostly through the drift region 62a. Therefore, the high voltage device 600 according to the present invention has a relatively lower conductive resistance as compared to the prior art.

The body region 66 has a second conductivity type, and is formed in the well 62 in the operation region 63a. The body region 66 is located beneath and in contact with the top surface 61a in the vertical direction. The body region 66 contacts the high concentration region 62′ of the well 62 in the channel direction (as indicated by the dashed arrow in the figure). The body contact 66′ has the second conductivity type, and is an electrical contact of the body region 66. The body contact 66′ is formed in the body region 66, beneath the top surface 61a and in contact with the top surface 61a in the vertical direction. The gate 67 is formed on the top surface 61a of the semiconductor layer 61′ in the operation region 63a. Part of the body region 66 near the top surface 61a, under the gate 67 in the vertical direction and between the source 68 and the well 62 in the channel direction, is an inversion region 66a, which serves as an inversion current channel in the ON operation of the high voltage device 600, wherein the inversion region 66a is located right below the gate 67 and in contact with the gate 67, and the inversion region 66a is located right below the first trench 65.

Still referring to FIG. 6, the source 68 and the drain 69 have the first conductivity type. The source 68 and the drain 69 are formed in the operation region 63a, beneath the top surface 61a and in contact with the top surface 61a in the vertical direction. The source 68 and the drain 69 are located at two different sides out of the gate 67 respectively, wherein the source 68 is located in the body region 66, at one side of the gate 67, and the drain 69 is located in the well 62 at the other side of the gate 67 which is away from the body region 66. Part of the well 62 which is near the top surface 61a, and between the body region 66 and the drain 69 in the channel direction, is the drift region 62a. The drift region 62a serves as a drift current channel in an ON operation of the high voltage device 600.

Still referring to FIG. 6, the top region 621 has the second conductivity type, and is formed in the well 62, right below and in contact with the drift oxide region 64. The top region 621 increases the breakdown voltage of the high voltage device 600. In one preferable embodiment, the top region 621 is electrically floating or electrically connected to the source 68. When the top region 621 is electrically floating, the conductive resistance of the high voltage device 600 is decreased, and the breakdown voltage of the high voltage device 600 is increased. When the top region 621 is electrically connected to the source 68, a super junction is formed between the top region 621 and part of the well 62 around the top region 621, whereby the conductive resistance of the high voltage device 600 is decreased and the breakdown voltage of the high voltage device 600 is increased as well.

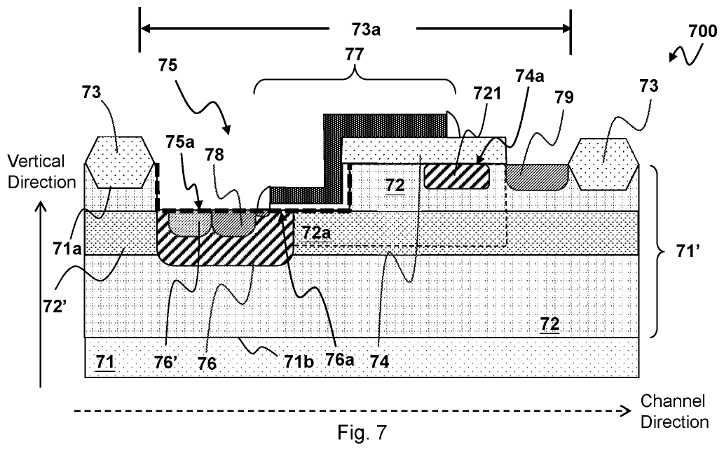

Please refer to FIG. 7, which shows a sixth embodiment of the present invention. FIG. 7 shows a cross-section view of a high voltage device 700. As show in FIG. 7, the high voltage device 700 includes a semiconductor layer 71′, a well 72, an isolation region 73, a drift oxide region 74, a body region 76, a body contact 76′, a gate 77, a source 78, a drain 79, and a top region 721. The semiconductor layer 71′ is formed on the substrate 71, wherein the semiconductor layer 71′ has a top surface 71a and a bottom surface 71b opposite to the top surface 71a in a vertical direction (as indicated by the direction of the solid arrow in FIG. 7). The substrate 71 is, for example but not limited to, a P-type or N-type silicon substrate. The semiconductor layer 71′, for example, is formed on the substrate 71 by an epitaxial growth process step, or is a part of the substrate 71. The semiconductor layer 71′ can be formed by various methods known to a person having ordinary skill in the art, so the details thereof are not redundantly explained here.

Still referring to FIG. 7, the isolation region 73 is formed on and in contact with the top surface 71a, for defining an operation region 73a. The isolation region 73 is not limited to a local oxidation of silicon (LOCOS) structure as shown in FIG. 7, and may be a shallow trench isolation (STI) structure or a chemical vapor deposition (CVD) oxide structure. The drift oxide region 74 is formed on and in contact with the top surface 71a, and is located on and in contact with part of the drift region 72a (as indicated by the dashed line frame in FIG. 7) in the operation region 73a. In this embodiment, the drift oxide region 74 is for example a chemical vapor deposition (CVD) oxide structure as shown.

The semiconductor layer 71′ has a first trench 75 as indicated by a bold dashed folded line shown in FIG. 7. In one prefereable embodiment, after the well 72 is formed, the first trench 75 is formed by a lithography process step and an etch process step. Thus, the bottom surface 74a of the drift oxide region 74 is higher than the first trench bottom 75a of the first trench 75 in the vertical direction. In one preferable embodiment, a high concentration region 72′ is arranged to be located beneath and in contact with the first trench bottom 75a. As thus, when the high voltage device 700 operates in the ON operation, carriers with the first conductivity type flow mostly through the high concentration region 72′ in the drift region 72a, which has a relatively lower conductive resistance as compared to the prior art high voltage device 100. In one preferable embodiment, the depth of the first trench 75 is smaller than one micrometer.

The well 72 has the first conductivity type, and is formed in the operation region 773a of the semiconductor layer 71′. The well 72 is located beneath the top surface 71a and is in contact with the top surface 71a in the vertical direction. In one preferable embodiment, the well 72 includes the high concentration region 72′. The impurity concentration of the first conductivity type impurities of the high concentration region 72′ is higher than the impurity concentration of any other region of the well 72. The well is formed by for example but not limited to plural ion implantation process steps, wherein at least one of the ion implantation process steps forms the high concentration region 72′. In one preferable embodiment, the high concentration region 72′ is in contact with the body region 76, and serves as a major channel for the first conductivity type carriers to flow through, whereby the first conductivity type carriers flow mostly through the drift region 72a. Therefore, the high voltage device 700 according to the present invention has a relatively lower conductive resistance as compared to the prior art.

The body region 76 has a second conductivity type, and is formed in the well 72 in the operation region 73a. The body region 76 is located beneath and in contact with the top surface 71a in the vertical direction. The body region 76 contacts the high concentration region 72′ of the well 72 in the channel direction (as indicated by the dashed arrow in the figure). The body contact 76′ has the second conductivity type, and is an electrical contact of the body region 76. The body contact 76′ is formed in the body region 76, beneath the top surface 71a and in contact with the top surface 71a in the vertical direction. The gate 77 is formed on the top surface 71a of the semiconductor layer 71′ in the operation region 73a. Part of the body region 76 near the top surface 71a, under the gate 77 in the vertical direction and between the source 78 and the well 72 in the channel direction, is an inversion region 76a, which serves as an inversion current channel in the ON operation of the high voltage device 700, wherein the inversion region 76a is located right below the gate 77 and in contact with the gate 77, and the inversion region 76a is located right below the first trench 75.

Still referring to FIG. 7, the source 78 and the drain 79 have the first conductivity type. The source 78 and the drain 79 are formed in the operation region 73a, beneath the top surface 71a and in contact with the top surface 71a in the vertical direction. The source 78 and the drain 79 are located at two different sides out of the gate 77 respectively, wherein the source 78 is located in the body region 76, at one side of the gate 77, and the drain 79 is located in the well 72 at the other side of the gate 77 which is away from the body region 76. Part of the well 72 which is near the top surface 71a, and between the body region 76 and the drain 79 in the channel direction, is the drift region 72a. The drift region 72a serves as a drift current channel in an ON operation of the high voltage device 700.

Still referring to FIG. 7, the top region 721 has the second conductivity type, and is formed in the well 72, right below and in contact with the drift oxide region 74. The top region 721 increases the breakdown voltage of the high voltage device 700. In one preferable embodiment, the top region 721 is electrically floating or electrically connected to the source 78. When the top region 721 is electrically floating, the conductive resistance of the high voltage device 700 is decreased, and the breakdown voltage of the high voltage device 700 is increased. When the top region 721 is electrically connected to the source 78, a super junction is formed between the top region 721 and part of the well 72 around the top region 721, whereby the conductive resistance of the high voltage device 700 is decreased and the breakdown voltage of the high voltage device 700 is increased as well.

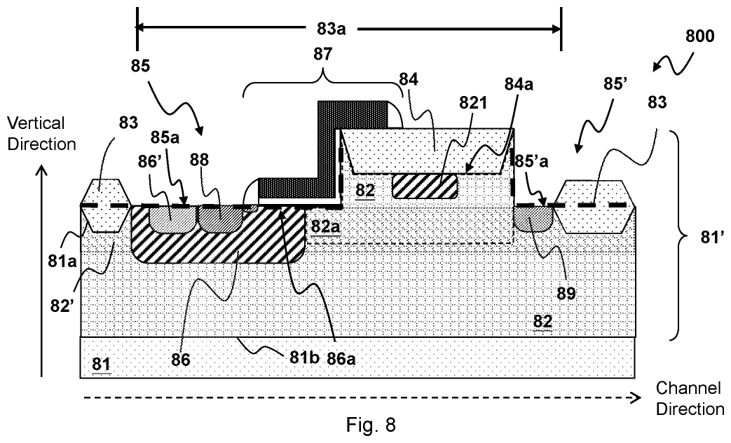

Please refer to FIG. 8, which shows a seventh embodiment of the present invention. FIG. 8 shows a cross-section view of a high voltage device 800. As show in FIG. 8, the high voltage device 800 includes a semiconductor layer 81′, a well 82, an isolation region 83, a drift oxide region 84, a body region 86, a body contact 86′, a gate 87, a source 88, a drain 89, and a top region 821. The semiconductor layer 81′ is formed on the substrate 81, and has a top surface 81a and a bottom surface 81b opposite to the top surface 81a in the vertical direction (as indicated by the direction of a solid arrow shown in FIG. 8, and the same hereinafter). The substrate 81 is, for example but not limited to, a P-type or N-type silicon substrate. The semiconductor layer 81′, for example, is formed on the substrate 81 by an epitaxial growth process step, or is a part of the substrate 81. The semiconductor layer 81′ can be formed by various methods as known to a person having ordinary skill in the art, so the details thereof are not redundantly explained here.

Still referring to FIG. 8, the isolation region 83 is formed on and in contact with the top surface 81a, for defining an operation region 83a. The isolation region 83 is not limited to a local oxidation of silicon (LOCOS) structure as shown in FIG. 8, and may be a shallow trench isolation (STI) structure or a chemical vapor deposition (CVD) oxide structure. The drift oxide region 84 is formed on and in contact with the top surface 81a, and is located on and in contact with part of the drift region 82a (as indicated by the dashed line frame in FIG. 8) in the operation region 83a. In this embodiment, the drift oxide region 84 is for example a shallow trench isolation (STI) structure as shown.

As indicated by a bold dashed folded line shown in FIG. 8, the semiconductor layer 81′ includes a first trench 85 and a second trench 85′. In a preferable embodiment, after the well 82 is formed, the first trench 85 and the second trench 85′ are formed by a lithography process step and an etch process step. Thus, the bottom surface 84a of the drift oxide region 84 is higher than the first trench bottom 85a of the first trench 85 and a second trench bottom 85′a of the second trench 85′. In one preferable embodiment, a high concentration region 82′ is arranged to be located beneath and in contact with the first trench bottom 85 and the second trench 85′. As thus, when the high voltage device 800 operates in the ON operation, the first conductivity type carriers flow even more through the high concentration region 82′ as compared to the first embodiment, to further reduce the conductive resistance. In a preferable embodiment, both the depths of the first trench 85 and the second trench 85′ are smaller than one micrometer.

The well 82 has the first conductivity type, and is formed in the operation region 83a of the semiconductor layer 81′, and the well 82 is located beneath the top surface 81a and in contact with the top surface 81a in the vertical direction. In one preferable embodiment, the well 82 includes the high concentration region 82′. The impurity concentration of the first conductivity type impurities of the high concentration region 82′ is higher than the impurity concentration of any other region of the well 82. The well 82 is formed by for example but not limited to plural ion implantation process steps, wherein at least one of the ion implantation process steps forms the high concentration region 82′. In one preferable embodiment, the high concentration region 82′ is in contact with the body region 86, and serves as a major channel for the first conductivity type carriers to flow through, whereby the first conductivity type carriers flow mostly through the drift region 82a. Therefore, the high voltage device 800 according to the present invention has a relatively lower conductive resistance as compared to the prior art.

The body region 86 has a second conductivity type, and is formed in the well 82 in the operation region 83a. The body region 86 is located beneath and in contact with the top surface 81a in the vertical direction. The body region 86 contacts the high concentration region 82′ of the well 82 in the channel direction (as indicated by the dashed arrow in the figure). The body contact 86′ has the second conductivity type, and is an electrical contact of the body region 86. The body contact 86′ is formed in the body region 86, beneath the top surface 81a and in contact with the top surface 81a in the vertical direction. The gate 87 is formed on the top surface 81a of the semiconductor layer 81′ in the operation region 83a. Part of the body region 86 near the top surface 81a, under the gate 87 in the vertical direction and between the source 88 and the well 82 in the channel direction, is an inversion region 86a, which serves as an inversion current channel in the ON operation of the high voltage device 800, wherein the inversion region 86a is located right below the gate 87 and in contact with the gate 87, and the inversion region 86a is located right below the first trench 85.

Still referring to FIG. 8, the source 88 and the drain 89 have the first conductivity type. The source 88 and the drain 89 are formed in the operation region 83a, beneath the top surface 81a and in contact with the top surface 81a in the vertical direction. The source 88 and the drain 89 are located at two different sides out of the gate 87 respectively, wherein the source 88 is located in the body region 86, at one side of the gate 87, and the drain 89 is located in the well 82 at the other side of the gate 87 which is away from the body region 86. Part of the well 82 which is near the top surface 81a, and between the body region 86 and the drain 89 in the channel direction, is the drift region 82a. The drift region 82a serves as a drift current channel in an ON operation of the high voltage device 800.

Still referring to FIG. 8, the top region 821 has the second conductivity type, and is formed in the well 82, right below and in contact with the drift oxide region 84. The top region 821 increases the breakdown voltage of the high voltage device 800. In one preferable embodiment, the top region 821 is electrically floating or electrically connected to the source 88. When the top region 821 is electrically floating, the conductive resistance of the high voltage device 800 is decreased, and the breakdown voltage of the high voltage device 800 is increased. When the top region 821 is electrically connected to the source 88, a super junction is formed between the top region 821 and part of the well 82 around the top region 821, whereby the conductive resistance of the high voltage device 800 is decreased and the breakdown voltage of the high voltage device 800 is increased as well.

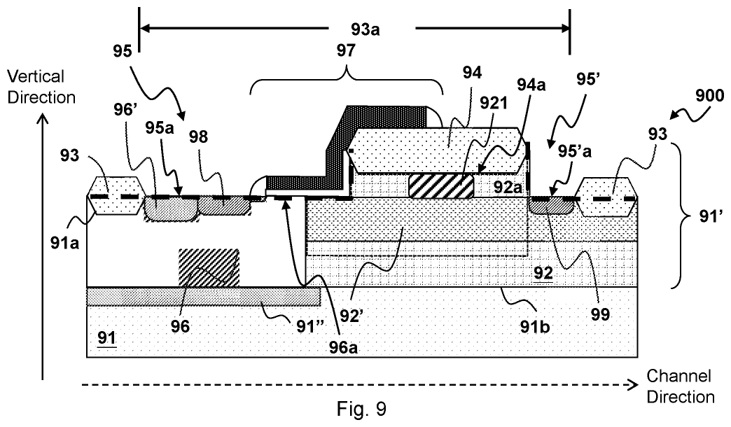

Please refer to FIG. 9, which shows an eighth embodiment of the present invention. FIG. 9 shows a cross-section view of a high voltage device 900. As show in FIG. 9, the high voltage device 900 includes a semiconductor layer 91′, a buried layer 91″, a drift well 92, an isolation region 93, a drift oxide region 94, a channel well 96, a well contact 96′, a gate 97, a source 98, a drain 99, and a top region 921. The semiconductor layer 91′ is formed on the substrate 91, and has a top surface 91a and a bottom surface 91b opposite to the top surface 91a in the vertical direction (as indicated by the direction of a solid arrow shown in FIG. 9, and the same hereinafter). The substrate 91 is, for example but not limited to, a P-type or N-type silicon substrate. The semiconductor layer 91′, for example, is formed on the substrate 91 by an epitaxial growth process step, or is a part of the substrate 91. The semiconductor layer 91′ can be formed by various methods as known to a person having ordinary skill in the art, so the details thereof are not redundantly explained here.

Still referring to FIG. 9, the isolation region 93 is formed on and in contact with the top surface 91a, for defining an operation region 93a. The isolation region 93 is not limited to a local oxidation of silicon (LOCOS) structure as shown in FIG. 9, and may be a shallow trench isolation (STI) structure or a chemical vapor deposition (CVD) oxide structure. The drift oxide region 94 is formed on and in contact with the top surface 91a, and is located on and in contact with part of the drift region 92a (as indicated by the dashed line frame in FIG. 9) in the operation region 93a. In this embodiment, the drift oxide region 94 can be formed, for example, by the same process steps which form the isolation region 93, so that the drift oxide region 94 and the isolation region 93 are formed at the same time.

As indicated by a bold dashed folded line shown in FIG. 9, the semiconductor layer 91′ includes a first trench 95 and a second trench 95′. In a preferable embodiment, after the drift well 92 and the channel well 96 are formed, the first trench 95 and the second trench 95′ are formed by a lithography process step and an etch process step. Thus, the bottom surface 94a of the drift oxide region 94 is higher than the first trench bottom 95a of the first trench 95 and the second trench bottom 95′a of the second trench 95′. In one preferable embodiment, a high concentration region 92′ is arranged to be located beneath and in contact with the first trench bottom 95 and the second trench 95′. This embodiment is different from the first embodiment in that, in this embodiment, the semiconductor layer 91′ further includes the second trench 95′. As thus, when the high voltage device 900 operates in the ON operation, the first conductivity type carriers flow even more through the high concentration region 92′ as compared to the first embodiment, to further reduce the conductive resistance. In a preferable embodiment, both the depths of the first trench 95 and the second trench 95′ are smaller than one micrometer.

The drift well 92 has the first conductivity type, and is formed in the operation region 93a of the semiconductor layer 91′, and the drift well 92 is located beneath the top surface 91a and in contact with the top surface 91a in the vertical direction. In one preferable embodiment, the drift well 92 includes the high concentration region 92′. The impurity concentration of the first conductivity type impurities of the high concentration region 92′ is higher than the impurity concentration of any other region of the drift well 92. The drift well 92 is formed by for example but not limited to plural ion implantation process steps, wherein at least one of the ion implantation process steps forms the high concentration region 92′. In one preferable embodiment, the high concentration region 92′ is in contact with the channel well 96, and serves as a major channel for the first conductivity type carriers to flow through, whereby the first conductivity type carriers flow mostly through the drift region 92a. Therefore, the high voltage device 900 according to the present invention has a relatively lower conductive resistance as compared to the prior art.

The channel well 96 has a second conductivity type, and is formed in the semiconductor layer 91′ in the operation region 93a. The channel well 96 is located beneath and in contact with the top surface 91a in the vertical direction. The channel well 96 contacts the high concentration region 92′ of the drift well 92 in the channel direction (as indicated by the dashed arrow in the figure). The channel contact 96′ has the second conductivity type, and is an electrical contact of the channel well 96. The channel contact 96′ is formed in the channel well 96, beneath the top surface 91a and in contact with the top surface 91a in the vertical direction. The gate 97 is formed on the top surface 91a of the semiconductor layer 91′ in the operation region 93a. Part of the channel well 96 near the top surface 91a, under the gate 97 in the vertical direction and between the source 98 and the drift well 92 in the channel direction, is an inversion region 96a, which serves as the inversion current channel in the ON operation of the high voltage device 900, wherein the inversion region 96a is located right below the first trench 95. The channel well 96 is in contact with the drift well 92 in the channel direction, and contacts the buried layer 91″ in the vertical direction.

Still referring to FIG. 9, the source 98 and the drain 99 have the first conductivity type. The source 98 and the drain 99 are formed in the operation region 93a, beneath the top surface 91a and in contact with the top surface 91a in the vertical direction. The source 98 and the drain 99 are located at two different sides out of the gate 97 respectively, wherein the source 98 is located in the channel well 96, at one side of the gate 97, and the drain 99 is located in the drift well 92 at the other side of the gate 97 which is away from the channel well 96. Part of the drift well 92 which is near the top surface 91a, and between the channel well 96 and the drain 99 in the channel direction, is the drift region 92a. The drift region 92a serves as the drift current channel in the ON operation of the high voltage device 900.

Still referring to FIG. 9, the top region 921 has the second conductivity type, and is formed in the drift well 92, right below and in contact with the drift oxide region 94. The top region 921 increases the breakdown voltage of the high voltage device 900. In one preferable embodiment, the top region 921 is electrically floating or electrically connected to the source 98. When the top region 921 is electrically floating, the conductive resistance of the high voltage device 900 is decreased, and the breakdown voltage of the high voltage device 900 is increased. When the top region 921 is electrically connected to the source 98, a super junction is formed between the top region 921 and part of the drift well 92 around the top region 921, whereby the conductive resistance of the high voltage device 900 is decreased and the breakdown voltage of the high voltage device 900 is increased as well.

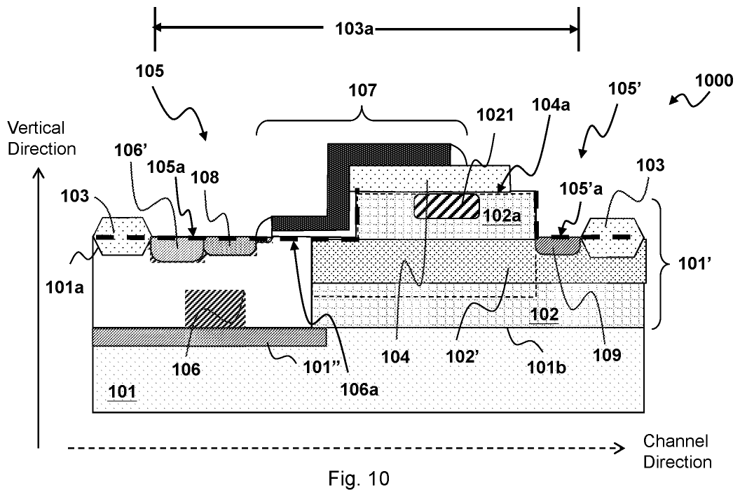

Please refer to FIG. 10, which shows a ninth embodiment of the present invention. FIG. 10 shows a cross-section view of a high voltage device 1000. As show in FIG. 10, the high voltage device 1000 includes a semiconductor layer 101′, a buried layer 101″, a drift well 102, an isolation region 103, a drift oxide region 104, a channel well 106, a well contact 106′, a gate 107, a source 108, a drain 109, and a top region 1021. The semiconductor layer 101′ is formed on the substrate 101, and has a top surface 101a and a bottom surface 101b opposite to the top surface 101a in the vertical direction (as indicated by the direction of a solid arrow shown in FIG. 10, and the same hereinafter). The substrate 101 is, for example but not limited to, a P-type or N-type silicon substrate. The semiconductor layer 101′, for example, is formed on the substrate 101 by an epitaxial growth process step, or is a part of the substrate 101. The semiconductor layer 101′ can be formed by various methods as known to a person having ordinary skill in the art, so the details thereof are not redundantly explained here.

Still referring to FIG. 10, the isolation region 103 is formed on and in contact with the top surface 101a, for defining an operation region 103a. The isolation region 103 is not limited to a local oxidation of silicon (LOCOS) structure as shown in FIG. 10, and may be a shallow trench isolation (STI) structure or a chemical vapor deposition (CVD) oxide structure. The drift oxide region 104 is formed on and in contact with the top surface 101a, and is located on and in contact with part of the drift region 102a (as indicated by the dashed line frame in FIG. 10) in the operation region 103a. In this embodiment, the drift oxide region 104 is for example a chemical vapor deposition (CVD) oxide structure as shown.

As indicated by a bold dashed folded line shown in FIG. 10, the semiconductor layer 101′ includes a first trench 105 and a second trench 105′. In a preferable embodiment, after the drift well 102 and the channel well 106 are formed, the first trench 105 and the second trench 105′ are formed by a lithography process step and an etch process step. Thus, the bottom surface 104a of the drift oxide region 104 is higher than the first trench bottom 105a of the first trench 105 and the second trench bottom 105′a of the second trench 105′. In one preferable embodiment, a high concentration region 102′ is arranged to be located beneath and in contact with the first trench bottom 105 and the second trench 105′. As thus, when the high voltage device 1000 operates in the ON operation, the first conductivity type carriers flow mostly through the high concentration region 102′, to reduce the conductive resistance. In a preferable embodiment, both the depths of the first trench 105 and the second trench 105′ are smaller than one micrometer.

The drift well 102 has the first conductivity type, and is formed in the operation region 103a of the semiconductor layer 101′, and the drift well 102 is located beneath the top surface 101a and in contact with the top surface 101a in the vertical direction. In one preferable embodiment, the drift well 102 includes the high concentration region 102′. The impurity concentration of the first conductivity type impurities of the high concentration region 102′ is higher than the impurity concentration of any other region of the drift well 102. The drift well 102 is formed by for example but not limited to plural ion implantation process steps, wherein at least one of the ion implantation process steps forms the high concentration region 102′. In one preferable embodiment, the high concentration region 102′ is in contact with the channel well 106, and serves as a major channel for the first conductivity type carriers to flow through, whereby the first conductivity type carriers flow mostly through the drift region 102a. Therefore, the high voltage device 1000 according to the present invention has a relatively lower conductive resistance as compared to the prior art.

The channel well 106 has a second conductivity type, and is formed in the semiconductor layer 101′ in the operation region 103a. The channel well 106 is located beneath and in contact with the top surface 101a in the vertical direction. The channel well 106 contacts the high concentration region 102′ of the drift well 102 in the channel direction (as indicated by the dashed arrow in the figure). The channel contact 106′ has the second conductivity type, and is an electrical contact of the channel well 106. The channel contact 106′ is formed in the channel well 106, beneath the top surface 101a and in contact with the top surface 101a in the vertical direction. The gate 107 is formed on the top surface 101a of the semiconductor layer 101′ in the operation region 103a. Part of the channel well 106 near the top surface 101a, under the gate 107 in the vertical direction and between the source 108 and the drift well 102 in the channel direction, is an inversion region 106a, which serves as the inversion current channel in the ON operation of the high voltage device 1000, wherein the inversion region 106a is located right below the first trench 105. The channel well 106 is in contact with the drift well 102 in the channel direction, and contacts the buried layer 101″ in the vertical direction.

Still referring to FIG. 10, the source 108 and the drain 109 have the first conductivity type. The source 108 and the drain 109 are formed in the operation region 103a, beneath the top surface 101a and in contact with the top surface 101a in the vertical direction. The source 108 and the drain 109 are located at two different sides out of the gate 107 respectively, wherein the source 108 is located in the channel well 106, at one side of the gate 107, and the drain 109 is located in the drift well 102 at the other side of the gate 107 which is away from the channel well 106. Part of the drift well 102 which is near the top surface 101a, and between the channel well 106 and the drain 109 in the channel direction, is the drift region 102a. The drift region 102a serves as the drift current channel in the ON operation of the high voltage device 1000.

Still referring to FIG. 10, the top region 1021 has the second conductivity type, and is formed in the drift well 102, right below and in contact with the drift oxide region 104. The top region 1021 increases the breakdown voltage of the high voltage device 1000. In one preferable embodiment, the top region 1021 is electrically floating or electrically connected to the source 108. When the top region 1021 is electrically floating, the conductive resistance of the high voltage device 1000 is decreased, and the breakdown voltage of the high voltage device 1000 is increased. When the top region 1021 is electrically connected to the source 108, a super junction is formed between the top region 1021 and part of the drift well 102 around the top region 1021, whereby the conductive resistance of the high voltage device 1000 is decreased and the breakdown voltage of the high voltage device 1000 is increased as well.

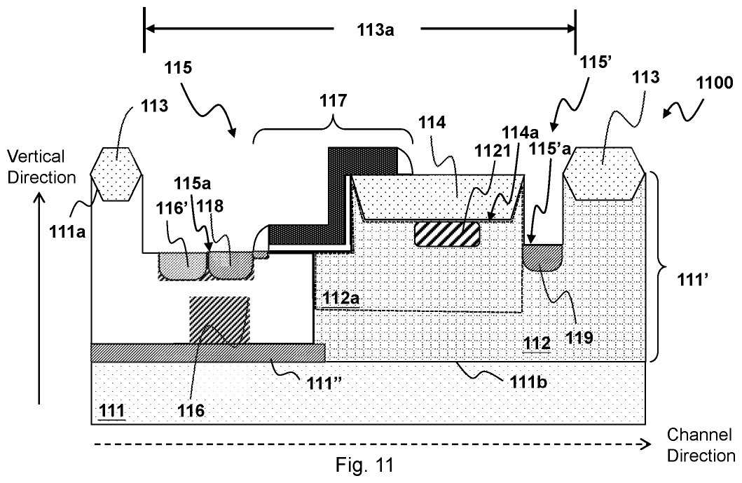

Please refer to FIG. 11, which shows a tenth embodiment of the present invention. FIG. 11 shows a cross-section view of a high voltage device 1100. As show in FIG. 11, the high voltage device 1100 includes a semiconductor layer 111′, a buried layer 111″, a drift well 112, an isolation region 113, adrift oxide region 114, a channel well 116, a well contact 116′, a gate 117, a source 118, a drain 119, and a top region 1121. The semiconductor layer 111′ is formed on the substrate 111, and has a top surface 111a and a bottom surface 111b opposite to the top surface 111a in the vertical direction (as indicated by the direction of a solid arrow shown in FIG. 11, and the same hereinafter). The substrate 111 is, for example but not limited to, a P-type or N-type silicon substrate. The semiconductor layer 111′, for example, is formed on the substrate 111 by an epitaxial growth process step, or is a part of the substrate 111. The semiconductor layer 111′ can be formed by various methods as known to a person having ordinary skill in the art, so the details thereof are not redundantly explained here.

Still referring to FIG. 11, the isolation region 113 is formed on and in contact with the top surface 111a, for defining an operation region 113a. The isolation region 113 is not limited to a local oxidation of silicon (LOCOS) structure as shown in FIG. 11, and may be a shallow trench isolation (STI) structure or a chemical vapor deposition (CVD) oxide structure. The drift oxide region 114 is formed on and in contact with the top surface 111a, and is located on and in contact with part of the drift region 112a (as indicated by the dashed line frame in FIG. 11) in the operation region 113a. In this embodiment, the drift oxide region 114 is for example a shallow trench isolation (STI) structure as shown.

As indicated by a bold dashed folded line shown in FIG. 11, the semiconductor layer 111′ includes a first trench 115 and a second trench 115′. In a preferable embodiment, after the drift well 112 and the channel well 116 are formed, the first trench 115 and the second trench 115′ are formed by a lithography process step and an etch process step. Thus, the bottom surface 114a of the drift oxide region 114 is higher than the first trench bottom 115a of the first trench 115 and the second trench bottom 115′a of the second trench 115′. In one preferable embodiment, a high concentration region 112′ is arranged to be located beneath and in contact with the first trench bottom 115 and the second trench 115′. As thus, when the high voltage device 1100 operates in the ON operation, the first conductivity type carriers flow mostly through the high concentration region 112′, to reduce the conductive resistance. In a preferable embodiment, both the depths of the first trench 115 and the second trench 115′ are smaller than one micrometer.

The drift well 112 has the first conductivity type, and is formed in the operation region 113a of the semiconductor layer 111′, and the drift well 112 is located beneath the top surface 111a and in contact with the top surface 111a in the vertical direction. In one preferable embodiment, the drift well 112 includes the high concentration region 112′. The impurity concentration of the first conductivity type impurities of the high concentration region 112′ is higher than the impurity concentration of any other region of the drift well 112. The drift well 112 is formed by for example but not limited to plural ion implantation process steps, wherein at least one of the ion implantation process steps forms the high concentration region 112′. In one preferable embodiment, the high concentration region 112′ is in contact with the channel well 116, and serves as a major channel for the first conductivity type carriers to flow through, whereby the first conductivity type carriers flow mostly through the drift region 112a. Therefore, the high voltage device 1100 according to the present invention has a relatively lower conductive resistance as compared to the prior art.

The channel well 116 has a second conductivity type, and is formed in the semiconductor layer 111′ in the operation region 113a. The channel well 116 is located beneath and in contact with the top surface 111a in the vertical direction. The channel well 116 contacts the high concentration region 112′ of the drift well 112 in the channel direction (as indicated by the dashed arrow in the figure). The channel contact 116′ has the second conductivity type, and is an electrical contact of the channel well 116. The channel contact 116′ is formed in the channel well 116, beneath the top surface 111a and in contact with the top surface 111a in the vertical direction. The gate 117 is formed on the top surface 111a of the semiconductor layer 111′ in the operation region 113a. Part of the channel well 116 near the top surface 111a, under the gate 117 in the vertical direction and between the source 118 and the drift well 112 in the channel direction, is an inversion region 116a, which serves as the inversion current channel in the ON operation of the high voltage device 1100, wherein the inversion region 116a is located right below the first trench 115. The channel well 116 is in contact with the drift well 112 in the channel direction, and contacts the buried layer 111″ in the vertical direction.

Still referring to FIG. 11, the source 118 and the drain 119 have the first conductivity type. The source 118 and the drain 119 are formed in the operation region 113a, beneath the top surface 111a and in contact with the top surface 111a in the vertical direction. The source 118 and the drain 119 are located at two different sides out of the gate 117 respectively, wherein the source 118 is located in the channel well 116, at one side of the gate 117, and the drain 119 is located in the drift well 112 at the other side of the gate 117 which is away from the channel well 116. Part of the drift well 112 which is near the top surface 111a, and between the channel well 116 and the drain 119 in the channel direction, is the drift region 112a. The drift region 112a serves as the drift current channel in the ON operation of the high voltage device 1100.

Still referring to FIG. 11, the top region 1121 has the second conductivity type, and is formed in the drift well 112, right below and in contact with the drift oxide region 114. The top region 1121 increases the breakdown voltage of the high voltage device 1100. In one preferable embodiment, the top region 1121 is electrically floating or electrically connected to the source 118. When the top region 1121 is electrically floating, the conductive resistance of the high voltage device 1100 is decreased, and the breakdown voltage of the high voltage device 1100 is increased. When the top region 1121 is electrically connected to the source 118, a super junction is formed between the top region 1121 and part of the drift well 112 around the top region 1121, whereby the conductive resistance of the high voltage device 1100 is decreased and the breakdown voltage of the high voltage device 1100 is increased as well.

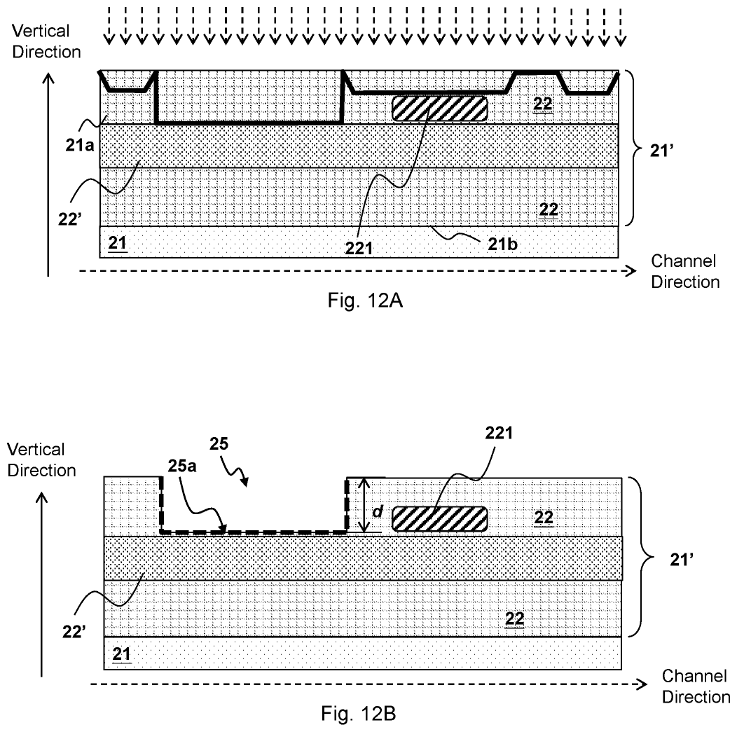

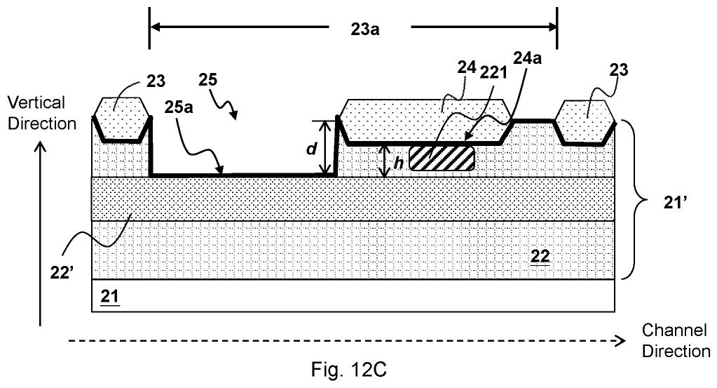

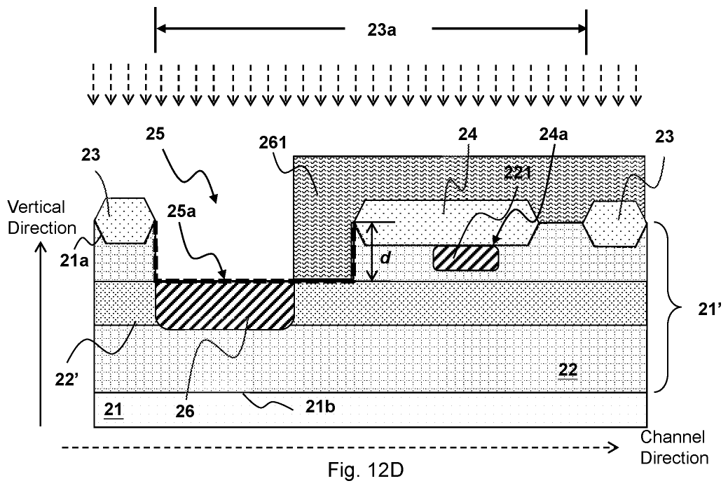

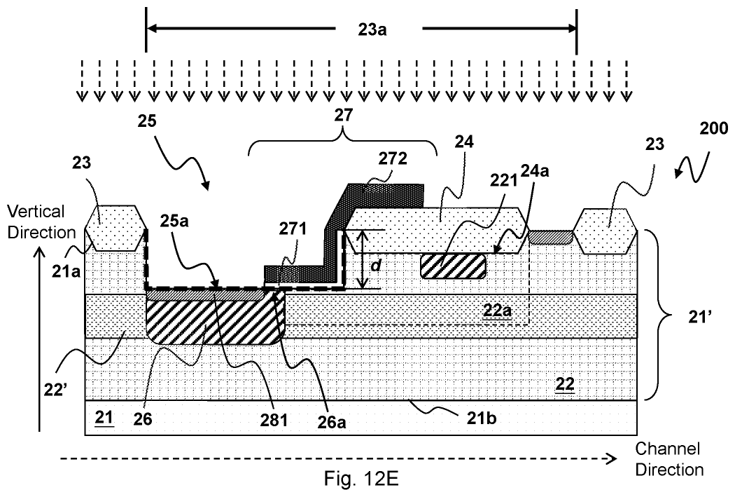

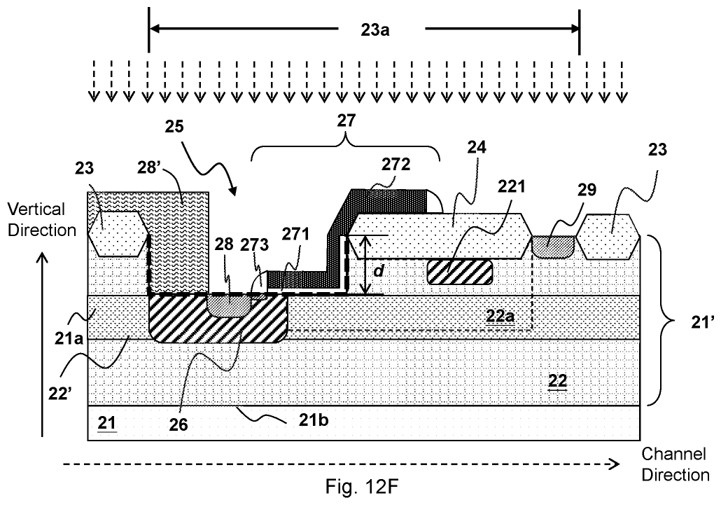

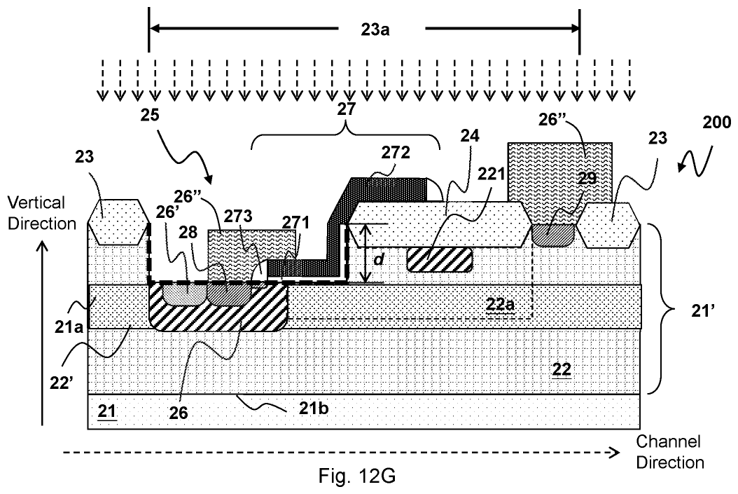

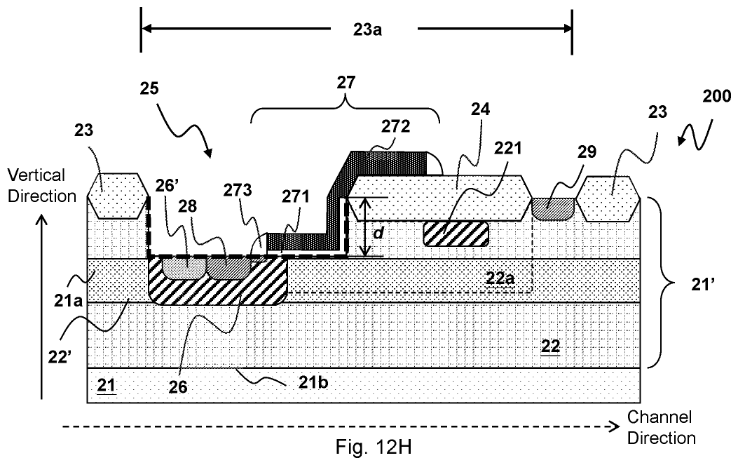

Please refer to FIGS. 12A-12H, which show an eleventh embodiment of the present invention. FIGS. 12A-12H show cross-section views of a manufacturing method of the high voltage device 200. As show in FIG. 12A, first, a semiconductor layer 21′ is formed on a substrate 21, wherein the semiconductor layer 21′ has a top surface (which has final shape 21a) and a bottom surface 21b opposite to the top surface in a vertical direction (as indicated by the direction of a solid arrow shown in FIG. 12). When the semiconductor layer 21′ is just formed, the first trench 25, the isolation region 23, and the drift oxide region 24 have not been formed, and thus the top surface has not been its final shape yet (the final shape of the top surface 21a is indicated by a bold folded line shown in FIG. 12A). The substrate 21 is, for example but not limited to, a P-type or N-type silicon substrate. The semiconductor layer 21′, for example, is formed on the substrate 21 by an epitaxial process step, or is a part of the substrate 21. The semiconductor layer 21′ can be formed by various methods as known to a person having ordinary skill in the art, so the details thereof are not redundantly explained here.

Still referring to FIG. 12A, a well 22 is formed. The well 22 has the first conductivity type, and is formed in the operation region 23a of the semiconductor layer 21′. The well 22 is located beneath the top surface 21a and is in contact with the top surface 21a in the vertical direction. In one preferable embodiment, the well 22 is formed for example by plural ion implantation process steps which implant impurities of the first conductivity type in the semiconductor layer 21′, wherein at least one of the ion implantation process steps forms the high concentration region 22′, so that the well 22 includes a high concentration region 22′. An impurity concentration of the first conductivity type impurities of the high concentration region 22′ is higher than an impurity concentration of any other region of the well 22. In one preferable embodiment, the high concentration region 22′ is in contact with the body region 26, and serves as a major channel for the first conductivity type carriers to flow through, whereby the first conductivity type carriers flow mostly through the drift region 22a. Therefore, the high voltage device 200 according to the present invention has a relatively lower conductive resistance as compared to the prior art.

Still referring to FIG. 12A, next, the top region 221 is formed by for example but not limited to an ion implantation process step, which implant impurities of the second conductivity type on the high concentration region 22′ in the well 22. The top region 221 has the second conductivity type, and is formed right below and in contact with the drift oxide region 24 in the well 22 (the drift oxide region 24 will be formed later). The top region 221 increases the breakdown voltage of the high voltage device 200. In one preferable embodiment, the top region 221 is electrically floating or electrically connected to the source 28. When the top region 221 is electrically floating, the conductive resistance of the high voltage device 200 is decreased, and the breakdown voltage of the high voltage device 200 is increased. When the top region 221 is electrically connected to the source 28, a super junction is formed between the top region 221 and part of the well 22 around the top region 221, whereby the conductive resistance of the high voltage device 200 is decreased and the breakdown voltage of the high voltage device 200 is increased as well.

Next, referring to FIG. 12B, a first trench 25 is formed by a lithography process step and an etch process step, wherein the etch process step etches the semiconductor layer 21′ from top. The first trench 25 has a first trench bottom 25a which has a depth d. In one preferable embodiment, the depth d of the first trench 25 is smaller than one micrometer. In one preferable embodiment, a high concentration region 22′ is arranged to be located beneath and in contact with the first trench bottom 25a. As thus, when the high voltage device 200 operates in the ON operation, carriers with the first conductivity type flow mostly through the high concentration region 22′ in the drift region 22a, which has a relatively lower conductive resistance as compared to the prior art high voltage device 100.

Next, referring to FIG. 12C, the isolation region 23 and the drift oxide region 24 are formed on and in contact with the top surface 21a. The isolation region 23 defines the operation region 23a. The isolation region 23 is not limited to a local oxidation of silicon (LOCOS) structure as shown in the figures, and may be a shallow trench isolation (STI) structure or a chemical vapor deposition (CVD) oxide structure. The drift oxide region 24 is formed on and in contact with part of the drift region 22a in the operation region 23a (also referring to FIG. 2A) in the operation region 23a. The bottom surface 24a of the drift oxide region 24 is higher than the first trench bottom 25a by a height h.

Next, referring to FIG. 12D, a body region 26 is formed in the well 22 in the operation region 23a, and is located beneath and in contact with the top surface 21a in the vertical direction. The body region 26 has a second conductivity type. The body region 26 can be formed by, for example but not limited to, a lithography process step and an ion implantation process step, wherein the lithography process step includes forming a photo-resist layer 261 as a mask, and the ion implantation process step implants second conductivity type impurities into the well 22 in the form of accelerated ions, to form the body region 26. The body region 26 contacts the high concentration region 22′ of the well 22 in the channel direction (as indicated by the dashed arrow in the figure).

Next, referring to FIG. 12E, a dielectric layer 271 and a conductive layer 272 are formed on the top surface 21a of the semiconductor layer 21′ in the operation region 23a. In the vertical direction (as indicated by the solid arrow in FIG. 12E), part of the body region 26 is located right below the dielectric layer 271 and the conductive layer 272 of the gate 27, and is in contact with the dielectric layer 271 of the gate 27, to provide the inversion layer 26a of the high voltage device 200 in the ON operation, wherein the inversion layer 26a is located right below the first trench 25.

Still referring to FIG. 12E, for example, a lightly doped region 281 is formed after the dielectric layer 271 and the conductive layer 272 of the gate 27 are formed, wherein the lightly doped region 281 is for forming a current flowing channel right below the spacer layer 273 (to be formed later), to assist the ON operation. The lightly doped region 281 can be formed by, for example but not limited to an ion implantation process step, which implants first conductivity type impurities in the body region 26 in the form of accelerated ions, to form the lightly doped region 281. Note that the impurity concentration of the first conductivity type impurities of the lightly doped region 281 is relatively lower than that of the source 28 or the drain 29, and thus, the overlap regions of the lightly doped region 281 with the source 28 and the drain 29 can be ignored.

Next, referring to FIG. 12F, as shown in the figure, the spacer layer 273 is formed outside the two sides of the conductive layer 272, to complete the gate 27. Next, a source 28 and a drain 29 are formed in the operation region 23a, beneath the top surface 21a and in contact with the top surface 21a in the vertical direction. The source 28 and the drain 29 are located at two different sides out of the gate 27 respectively, wherein the source 28 is located in the body region 26, at one side of the gate 27, and the drain 29 is located in the well 22 at the other side of the gate 27 which is away from the body region 26. Part of the well 22 which is near the top surface 21a, and between the body region 26 and the drain 29 in the channel direction, is the drift region 22a. The drift region 22a serves as a drift current channel in an ON operation of the high voltage device 200. The source 28 and the drain 29 are located beneath and in contact with the top surface 21a in the vertical direction, and have the first conductivity type. The source 28 and the drain 29 can be formed by, for example but not limited to, a lithography process step and an ion implantation process step, wherein the lithography process step includes forming a photo-resist layer 28′ as a mask, and the ion implantation process step implants first conductivity type impurities into the body region 26 and the well 22 in the form of accelerated ions, to form the source 28 and the drain 29 respectively.

Next, referring to FIG. 12G, as shown in the figure, a body contact 26′ is formed in the body region 26. The body contact 26′ has a second conductivity type, and is an electrical contact of the body region 26. In the vertical direction, the body contact 26′ is formed beneath and in contact with the top surface 21a in the body region 26. The body contact 26′ can be formed by, for example but not limited to, a lithography process step and an ion implantation process step, wherein the lithography process step includes forming a photo-resist layer 26″ as a mask, and the ion implantation process step implants second conductivity type impurities into the body region 26 in the form of accelerated ions, to form the body contact 26′.

Next, as shown in FIG. 12H, the photo-resist layer 26″ is removed to form the high voltage device 200.

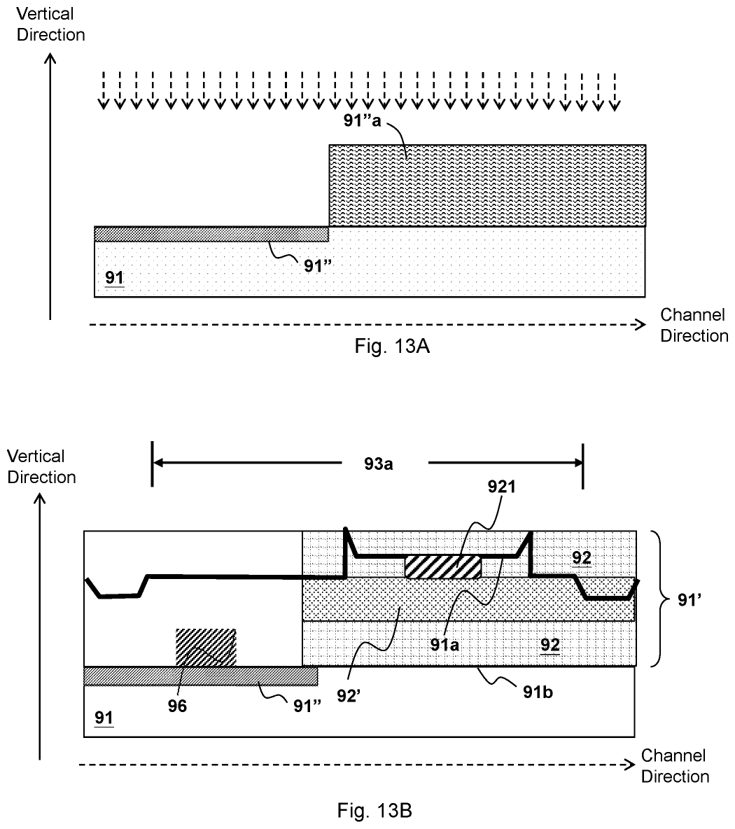

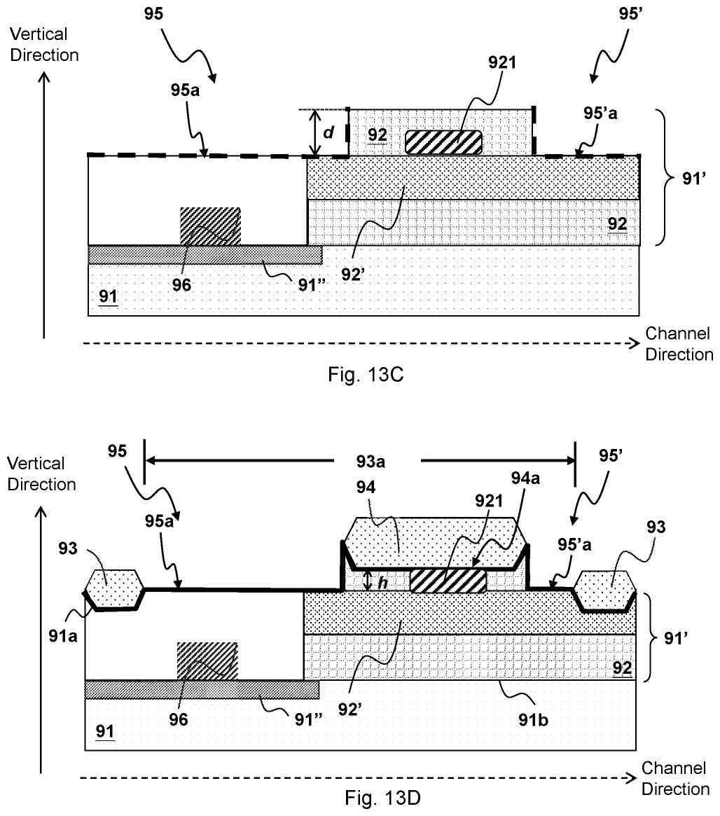

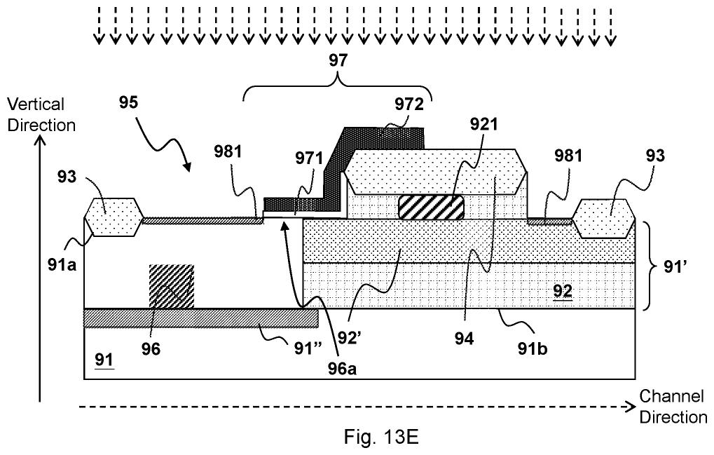

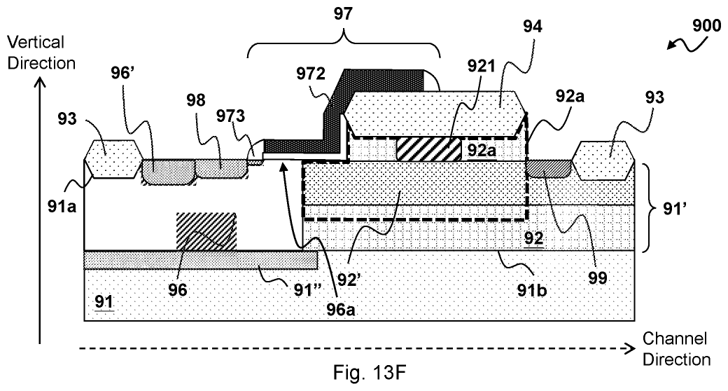

Please refer to FIGS. 13A-13F, which show a twelfth embodiment of the present invention. FIGS. 13A-13F show cross-section views of a manufacturing of the high voltage device 900. As show in FIG. 13A, first, a buried layer 91″ is formed. The buried layer 91″ can be formed by, for example but not limited to, a lithography process step and an ion implantation process step, wherein the lithography process step includes forming a photo-resist layer 91″ as a mask, and the ion implantation process step implants first conductivity type impurities into the substrate 91 in the form of accelerated ions, to form the buried layer 91″. The substrate 91 is, for example but not limited to, a P-type or N-type silicon substrate.

Next, referring to FIG. 13B, a semiconductor layer 91′ is formed on the substrate 91, wherein the semiconductor layer 91′ has a top surface (which has a final shape 91a) and a bottom surface 91b opposite to the top surface in the vertical direction (as indicated by the direction of a solid arrow shown in FIG. 13B). When the semiconductor layer 91′ is just formed, the first trench 95, the isolation region 93, and the drift oxide region 94 have not been formed yet, and thus the top surface has not become its final shape yet (the final shape of the top surface 91a is indicated by a bold folded line shown in FIG. 13A). The semiconductor layer 91′, for example, is formed on the substrate 91 by an epitaxial process step, or is a part of the substrate 91. The semiconductor layer 91′ can be formed by various methods as known to a person having ordinary skill in the art, so the details thereof are not redundantly explained here.

Next, still referring to FIG. 13B, a drift well 92 is formed for example by plural ion implantation process steps which implant impurities of the first conductivity type in the semiconductor layer 91′. The drift well 92 has the first conductivity type, and is formed in the operation region 93a of the semiconductor layer 91′. The drift well 92 is located beneath the top surface 91a and is in contact with the top surface 91a in the vertical direction. In one preferable embodiment, the drift well 92 includes a high concentration region 92′. The impurity concentration of the first conductivity type impurities of the high concentration region 92′ is higher than the impurity concentration of any other region of the drift well 92. The drift well 92 is formed by for example but not limited to the plural ion implantation process steps, wherein at least one of the ion implantation process steps forms the high concentration region 92′. In one preferable embodiment, the high concentration region 92′ is in contact with the channel well 96, and serves as a major channel for the first conductivity type carriers to flow through, whereby the first conductivity type carriers flow mostly through the drift region 92a. Therefore, the high voltage device 900 according to the present invention has a relatively lower conductive resistance as compared to the prior art.

Next, still referring to FIG. 13B, a channel well 96 is formed in the operation region 23a, and is located beneath and in contact with the top surface 91a in the vertical direction. The channel well 96 has the second conductivity type. The channel well 96 can be formed by, for example but not limited to, a lithography process step and an ion implantation process step, wherein the lithography process step includes forming a photo-resist layer as a mask, and the ion implantation process step implants second conductivity type impurities into the semiconductor layer 91′ in the form of accelerated ions, to form the channel well 96. The channel well 96 contacts the high concentration region 92′ of the drift well 92 in the channel direction (as indicated by the dashed arrow in the figure), and contacts the buried layer 91″ in the vertical direction.

Still referring to FIG. 13B, next, the top region 921 is formed by for example but not limited to an ion implantation process step, which implant impurities of the second conductivity type on the high concentration region 92′ in the drift well 92. The top region 921 has the second conductivity type, and is formed right below and in contact with the drift oxide region 94 in the well 92 (the drift oxide region 94 will be formed later). The top region 921 increases the breakdown voltage of the high voltage device 900. In one preferable embodiment, the top region 921 is electrically floating or electrically connected to the source 98. When the top region 921 is electrically floating, the conductive resistance of the high voltage device 900 is decreased, and the breakdown voltage of the high voltage device 900 is increased. When the top region 921 is electrically connected to the source 98, a super junction is formed between the top region 921 and part of the drift well 92 around the top region 921, whereby the conductive resistance of the high voltage device 900 is decreased and the breakdown voltage of the high voltage device 900 is increased as well.

Next, referring to FIG. 13C, a first trench 95 and a second trench 95′ are formed by etching the semiconductor layer 91′ from top. The first trench 95 and the second trench 95′ have a first trench bottom 95a and a second trench bottom 95′a respectively. As shown in FIG. 13C, the first trench bottom 95a has the depth d. In one preferable embodiment, the depth d of the first trench 95 is smaller than one micrometer. In one preferable embodiment, a high concentration region 92′ is arranged to be located beneath and in contact with the first trench bottom 95a and the second trench bottom 95′a. As thus, when the high voltage device 900 operates in the ON operation, carriers with the first conductivity type flow mostly through the high concentration region 92′ in the drift region 92a, which has a relatively lower conductive resistance as compared to the prior art high voltage device 100.

Next, referring to FIG. 13D, an isolation region 93 and a drift oxide region 94 are formed on and in contact with the top surface 91a. The isolation region 93 defines the operation region 93a. The isolation region 93 is not limited to a local oxidation of silicon (LOCOS) structure as shown in the figures, and may instead be a shallow trench isolation (STI) structure or a chemical vapor deposition (CVD) oxide structure. The drift oxide region 94 is formed on and in contact with part of the drift region 92a in the operation region 93a (also referring to FIG. 9). The bottom surface 94a of the drift oxide region 94 is higher than the first trench bottom 95a and the second trench bottom 95′a by a height h.

Next, referring to FIG. 13E, a dielectric layer 971 and a conductive layer 979 are formed on the top surface 91a of the semiconductor layer 91′ in the operation region 93a. In the vertical direction (as indicated by the solid arrow in FIG. 13E), part of the channel well 96 is located right below the dielectric layer 971 and the conductive layer 972 of the gate 97, and is in contact with the dielectric layer 971 of the gate 97, to provide the inversion layer 96a of the high voltage device 900 in the ON operation, wherein the inversion layer 96a is located right below the first trench 95.

Still referring to FIG. 13E, for example, a lightly doped region 981 is formed after the dielectric layer 971 and the conductive layer 979 of the gate 97 are formed, wherein the lightly doped region 981 is for forming a current flowing channel right below the spacer layer 973 (to be formed later), to assist the ON operation. The lightly doped region 981 can be formed by, for example but not limited to an ion implantation process step, which implants first conductivity type impurities in the body region 96 in the form of accelerated ions, to form the lightly doped region 981. Note that the impurity concentration of the first conductivity type impurities of the lightly doped region 981 is relatively lower than that of the source 98 or the drain 99, and thus, the overlap regions of the lightly doped region 981 with the source 98 and the drain 99 can be ignored.

Next, referring to FIG. 13F, the spacer layer 973 is formed outside the two sides of the conductive layer 972, to complete the gate 97. Next, a source 98 and a drain 99 are formed in the operation region 93a, beneath the top surface 91a and in contact with the top surface 91a in the vertical direction. The source 98 and the drain 99 are located at two different sides out of the gate 97 respectively, wherein the source 98 is located in the channel well 96, at one side of the gate 97, and the drain 99 is located in the drift well 92 at the other side of the gate 97 which is away from the channel well 96. Part of the drift well 92 which is near the top surface 91a, and between the channel well 96 and the drain 99 in the channel direction, is the drift region 92a. The drift region 92a serves as the drift current channel in the ON operation of the high voltage device 900. The source 98 and the drain 99 are located beneath and in contact with the top surface 91a in the vertical direction, and have the first conductivity type. The source 98 and the drain 99 can be formed by, for example but not limited to, a lithography process step and an ion implantation process step, wherein the lithography process step includes forming a photo-resist layer as a mask, and the ion implantation process step implants first conductivity type impurities into the channel well 96 and the drift well 92 in the form of accelerated ions, to form the source 98 and the drain 99 respectively.

Next, still referring to FIG. 13F, as shown in the figure, a well contact 96′ is formed in the channel well 96. The well contact 96′ has the second conductivity type, and is an electrical contact of the channel well 96. In the vertical direction, the well contact 96′ is formed beneath and in contact with the top surface 91a in the channel well 96. The well contact 96′ can be formed by, for example but not limited to, a lithography process step and an ion implantation process step, wherein the lithography process step includes forming a photo-resist layer as a mask, and the ion implantation process step implants second conductivity type impurities into the channel well 96 in the form of accelerated ions, to form the well contact 96′.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a deep well, may be added. For another example, the lithography technique is not limited to the mask technology but it can be electron beam lithography, immersion lithography, etc. Therefore, in the same spirit of the present invention, those skilled in the art can think of various equivalent variations and modifications, which should fall in the scope of the claims and the equivalents.

What is claimed is:

1. A high voltage device comprising:
a semiconductor layer formed on a substrate, wherein the semiconductor layer has a first trench;
a well having a first conductivity type, wherein the well is formed in the semiconductor layer;
a body region having a second conductivity type, wherein the body region is formed in the well;
a gate formed on the well and in contact with the well;
a source and a drain having the first conductivity type, wherein the source and the drain are located at different sides out of the gate respectively, wherein the source is located in the body region, and the drain is located in the well, wherein part of the well between the body region and the drain is a drift region, which serves as a drift current channel in an ON operation of the high voltage device;
a drift oxide region formed right above the drift region, wherein the drift oxide region has a bottom surface higher than a first trench bottom of the first trench; and
a top region having the second conductivity type, wherein the top region is formed in the well, right below and in contact with the drift oxide region;
wherein part of the body region between the source and the well is an inversion region, which serves as an inversion current channel in the ON operation of the high voltage device, wherein the inversion region is located right below the first trench.

2. The high voltage device of claim 1, wherein the drift oxide region includes a local oxidation of silicon (LOCOS) structure, a shallow trench isolation (STI) structure or a chemical vapor deposition (CVD) oxide structure.

3. The high voltage device of claim 1, wherein the gate includes:
a dielectric layer, which is formed on the body region and the well, and is in contact with the body region and the well;
a conductive layer, which is an electrical contact of the gate, and is formed on the dielectric layer and in contact with the dielectric layer; and
a spacer layer, which is formed at two sides of the conductive layer, as an electrical insulating layer of the gate.

4. The high voltage device of claim 3, wherein the dielectric layer includes a first part and a second part, wherein the first part has a first thickness, and is located right above the inversion region and in contact with the inversion region, and wherein the second part has a second thickness, and is located right above the drift region and in contact with the drift region, wherein the first thickness is smaller than the second thickness.

5. The high voltage device of claim 1, wherein the semiconductor layer further includes a second trench, and the drift oxide region is located between the first trench and the second trench; wherein the drain is located right below the second trench in the well, and the bottom of the drift oxide region is higher than a second trench bottom of the second trench.

6. The high voltage device of claim 1, wherein the well includes a high concentration region in contact with the body region, wherein an impurity concentration of the high concentration region is higher than an impurity concentration of any other region of the well.

7. The high voltage device of claim 5, wherein the well includes a high concentration region in contact with the body region, wherein an impurity concentration of the high concentration region is higher than an impurity concentration of any other region of the well.

8. The high voltage device of claim 1, wherein the first trench has a depth smaller than one micrometer.

9. The high voltage device of claim 1, wherein the top region is electrically floating or electrically connected to the source.

10. A manufacturing method of a high voltage device, comprising:
forming a semiconductor layer on a substrate;
forming a well having a first conductivity type, wherein the well is formed in the semiconductor layer;
forming a top region having the second conductivity type in the well;
forming a first trench by etching the semiconductor layer;
forming a drift oxide region on the well;
forming a body region having a second conductivity type, wherein the body region is formed in the well;
forming a gate on the well and in contact with the well; and
forming a source and a drain having the first conductivity type, wherein the source and the drain are located at different sides out of the gate respectively, wherein the source is located in the body region, and the drain is located in the well, wherein part of the well between the body region and the drain is a drift region, which serves as a drift current channel in an ON operation of the high voltage device;
wherein the drift oxide region is formed right above the drift region, wherein the drift oxide region has a bottom surface higher than a first trench bottom of the first trench;
wherein part of the body region between the source and the well is an inversion region, which serves as an inversion current channel in the ON operation of the high voltage device, wherein the inversion region is located right below the first trench;
wherein the top region is located right below and in contact with the drift oxide region.

11. The manufacturing method of claim 10, wherein the drift oxide region includes a local oxidation of silicon (LOCOS) structure, a shallow trench isolation (STI) structure or a chemical vapor deposition (CVD) oxide structure.

12. The manufacturing method of claim 10, wherein the gate includes:
a dielectric layer, which is formed on the body region and the well, and is in contact with the body region and the well;
a conductive layer, which is an electrical contact of the gate, and is formed on the dielectric layer and in contact with the dielectric layer; and
a spacer layer, which is formed at two sides of the conductive layer, as an electrical insulating layer of the gate.

13. The manufacturing method of claim 12, wherein the dielectric layer includes a first part and a second part, wherein the first part has a first thickness, and is located right above the inversion region and in contact with the inversion region, and wherein the second part has a second thickness, and is located right above the drift region and in contact with the drift region, wherein the first thickness is smaller than the second thickness.

14. The manufacturing method of claim 10, wherein the semiconductor layer further includes a second trench, and the drift oxide region is located between the first trench and the second trench; wherein the drain is located right below the second trench in the well, and the bottom of the drift oxide region is higher than a second trench bottom of the second trench.

15. The manufacturing method of claim 10, wherein the well includes a high concentration region in contact with the body region, wherein an impurity concentration of the high concentration region is higher than an impurity concentration of any other region of the well.

16. The manufacturing method of claim 14, wherein the well includes a high concentration region in contact with the body region, wherein an impurity concentration of the high concentration region is higher than an impurity concentration of any other region of the well.

17. The manufacturing method of claim 10, wherein the first trench has a depth smaller than one micrometer.

18. The manufacturing method of claim 10, wherein the top region is electrically floating or electrically connected to the source.

19. A high voltage device comprising:
a semiconductor layer formed on a substrate, wherein the semiconductor layer has a first trench;
a drift well having a first conductivity type, wherein the drift well is formed in the semiconductor layer;
a channel well having a second conductivity type, wherein the channel well is formed in the drift well, and is in contact with the drift well in a channel direction;
a buried layer having the first conductivity type, wherein the buried layer is formed below the channel well and in contact with the channel well;
a gate formed on part of the channel well and part of the drift well, wherein the gate is in contact with the channel well and the drift well;
a source and a drain having the first conductivity type, wherein the source and the drain are located at different sides out of the gate respectively, wherein the source is located in the channel well, and the drain is located in the drift well, wherein part of the drift well between the drain and the channel well is a drift region, which serves as a drift current channel in an ON operation of the high voltage device;
a drift oxide region formed right above the drift region, wherein the drift oxide region has a bottom surface higher than a first trench bottom of the first trench; and
a top region having the second conductivity type, wherein the top region is formed in the well, right below and in contact with the drift oxide region;
wherein part of the channel well between the source and the drift well in the channel direction is an inversion region, which serves as an inversion current channel in the ON operation of the high voltage device, wherein the inversion region is located right below the first trench.

20. The high voltage device of claim 19, wherein the drift oxide region includes a local oxidation of silicon (LOCOS) structure, a shallow trench isolation (STI) structure or a chemical vapor deposition (CVD) oxide structure.

21. The high voltage device of claim 19, wherein the gate includes:
a dielectric layer, which is formed on the body region and the well, and is in contact with the body region and the well;
a conductive layer, which is an electrical contact of the gate, and is formed on the dielectric layer and in contact with the dielectric layer; and
a spacer layer, which is formed at two sides of the conductive layer, as an electrical insulating layer of the gate.

22. The high voltage device of claim 21, wherein the dielectric layer includes a first part and a second part, wherein the first part has a first thickness, and is located right above the inversion region and in contact with the inversion region, and wherein the second part has a second thickness, and is located right above the drift region and in contact with the drift region, wherein the first thickness is smaller than the second thickness.

23. The high voltage device of claim 19, wherein the semiconductor layer further includes a second trench, and the drift oxide region is located between the first trench and the second trench; wherein the drain is located right below the second trench in the well, and the bottom of the drift oxide region is higher than a second trench bottom of the second trench.

24. The high voltage device of claim 19, wherein the drift well includes a high concentration region in contact with the channel well, wherein an impurity concentration of the high concentration region is higher than an impurity concentration of any other region of the drift well.

25. The high voltage device of claim 23, wherein the drift well includes a high concentration region in contact with the channel well, wherein an impurity concentration of the high concentration region is higher than an impurity concentration of any other region of the drift well.

26. The high voltage device of claim 19, wherein the top region is electrically floating or electrically connected to the source.

27. A manufacturing method of a high voltage device, comprising:
forming a buried layer having a first conductivity type in a substrate;
forming a semiconductor layer on the substrate;
forming a drift well having a first conductivity, wherein the drift well is formed in the semiconductor layer;
forming a channel well having a second conductivity type, wherein the channel well is in contact with the drift well in a channel direction, and contacts the buried layer in a vertical direction;
forming a top region having the second conductivity type in the well;
forming a first trench by etching the semiconductor layer;
forming a drift oxide region on the drift well;
forming a gate on part of the channel well and part of the drift well, wherein the gate is in contact with the channel well and the drift well; and
forming a source and a drain having the first conductivity type, wherein the source and the drain are located at different sides out of the gate respectively, wherein the source is located in the channel well, and the drain is located in the drift well, wherein part of the drift well between the drain and the channel well is a drift region, which serves as a drift current channel in an ON operation of the high voltage device;
wherein the drift oxide region has a bottom surface higher than a first trench bottom of the first trench;
wherein part of the channel well between the source and the drift well in the channel direction is an inversion region, which serves as an inversion current channel in the ON operation of the high voltage device, wherein the inversion region is located right below the first trench;
wherein the buried layer is formed below the channel well and in contact with the channel well;
wherein the top region is located right below and in contact with the drift oxide region.

28. The manufacturing method of claim 27, wherein the drift oxide region includes a local oxidation of silicon (LOCOS) structure, a shallow trench isolation (STI) structure or a chemical vapor deposition (CVD) oxide structure.

29. The manufacturing method of claim 27, wherein the gate includes:
a dielectric layer, which is formed on the body region and the well, and is in contact with the body region and the well;
a conductive layer, which is an electrical contact of the gate, and is formed on the dielectric layer and in contact with the dielectric layer; and
a spacer layer, which is formed at two sides of the conductive layer, as an electrical insulating layer of the gate.

30. The manufacturing method of claim 27, wherein the dielectric layer includes a first part and a second part, wherein the first part has a first thickness, and is located right above the inversion region and in contact with the inversion region, and wherein the second part has a second thickness, and is located right above the drift region and in contact with the drift region, wherein the first thickness is smaller than the second thickness.

31. The manufacturing method of claim 27, further comprising: forming a second trench, wherein the drift oxide region is located between the first trench and the second trench; wherein the drain is located right below the second trench in the drift well, and the bottom of the drift oxide region is higher than a second trench bottom of the second trench.

32. The manufacturing method of claim 27, wherein the drift well includes a high concentration region in contact with the channel well, wherein an impurity concentration of the high concentration region is higher than an impurity concentration of any other region of the drift well.

33. The manufacturing method of claim 31, wherein the drift well includes a high concentration region in contact with the channel well, wherein an impurity concentration of the high concentration region is higher than an impurity concentration of any other region of the drift well.

34. The manufacturing method of claim 27, wherein the top region is electrically floating or electrically connected to the source.
